(19) United States
(12) Patent Application Publication
(10) Pub. No.: US 2025/0258527 A1
(43) Pub. Date: Aug. 14, 2025

(54) WORKING ASSEMBLY AND ELECTRONIC DEVICE

(71) Applicant: CANAAN CREATIVE CO., LTD., Beijing (CN)

(72) Inventors: Shaohua ZHANG, Beijing (CN); Huan YANG, Beijing (CN); Nangeng ZHANG, Beijing (CN)

(21) Appl. No.: 19/184,501

(22) Filed: Apr. 21, 2025

Related U.S. Application Data
(63) Continuation of application No. PCT/CN2023/125702, filed on Oct. 20, 2023.

(30) Foreign Application Priority Data
Oct. 20, 2022 (CN) 202211291965.1
Nov. 11, 2022 (CN) 202211414790.9

(51) Int. Cl. G06F 1/20

(52) U.S. Cl. CPC G06F 1/206

(57) ABSTRACT

A working assembly and an electronic device. The working assembly is suitable for working in a heat-dissipating air duct. The working assembly comprises: a circuit board, a plurality of heat-generating components being provided on at least one side surface of the circuit board; and at least one heat sink provided on the circuit board. At an air outlet of the heat-dissipating air duct, an edge of the at least one heat sink close to the air outlet exceeds an edge of the circuit board close to the air outlet. The arrangement mode can reduce the maximum temperature difference between the heat-generating components close to the air outlet and the heat-generating components close to the air inlet, so that the temperature uniformity of the heat-generating components is improved.

### CROSS REFERENCE TO RELATED APPLICATIONS

This present application is a Continuation Application of International Application No. PCT/CN2023/125702, filed on Oct. 20, 2023, which claims priority to and benefits of Chinese Patent Application No. 202211291965.1, titled “WORKING ASSEMBLY AND ELECTRONIC DEVICE”, filed with the China National Intellectual Property Administration on Oct. 20, 2022, and Chinese Patent Application No. 202211414790.9, titled “WORKING ASSEMBLY AND ELECTRONIC DEVICE”, filed with the China National Intellectual Property Administration on Nov. 11, 2022. The entire contents of all of the above-identified applications are incorporated herein by reference.

### TECHNICAL FIELD

The present application relates to the field of heat dissipation technology, and in particular, to a working assembly and an electronic device.

### BACKGROUND

In the existing technology, heat-generating components including chips are usually disposed on a circuit board.

### SUMMARY

The present application provides in the embodiments a working assembly and an electronic device.

As one aspect of the embodiments of the present application, the present application provides in its embodiments a working assembly suitable for working in a heat-dissipating air duct, the working assembly including: a circuit board, a plurality of heat-generating components being provided on at least one side surface of the circuit board; and at least one heat sink being disposed on the circuit board; wherein, at the air outlet of the heat-dissipating air duct, an edge of at least one heat sink close to the air outlet exceeds an edge of the circuit board close to the air outlet.

In one implementation, there are a plurality of heat sinks, the plurality of heat sinks cover both sides of the circuit board, and edges of all of the heat sinks close to the air outlet exceed the edge of the circuit board close to the air outlet.

In one implementation, the surface of the circuit board is parallel to a first direction, which is a direction from an air inlet to the air outlet of the heat-dissipating air duct.

In one implementation, along the first direction, the dimension of the heat sink exceeds the dimension of the circuit board by 10 mm to 20 mm.

In one implementation, each heat sink includes a heat sink body and a plurality of heat sink fins disposed on the heat sink body, the heat sink body is parallel to the circuit board, the heat sink fins are perpendicular to the circuit board, and at least one of the heat sink fins is formed with at least one groove.

In one implementation, the groove is disposed at an end of the at least one of the heat sink fins close to the air outlet relative to the center of the heat sink.

In one implementation, the groove is disposed corresponding to the heat-generating components.

In one implementation, the plurality of heat sink fins of each heat sink are provided with the groove along a second direction, and a plurality of grooves are arranged along the second direction, wherein the second direction is perpendicular to the first direction.

In one implementation, the plurality of heat-generating components are arranged along the second direction, and at least one column of grooves is disposed opposite to at least one column of heat-generating components.

In one implementation, the dimension of the groove in the first direction is 2.5 mm to 3.5 mm.

In one implementation, the plurality of heat-generating components are arranged in a column, and in a second direction, centers of at least three or all of the heat-generating components are in a straight line, the second direction is perpendicular to a first direction, each heat sink includes a heat sink body and a plurality of heat sink fins, at least one of the heat sink fins includes a beveled portion, the height of the beveled portion gradually increases along the first direction, and an end of the beveled portion away from an air inlet corresponds to the position of a third column of heat-generating components, wherein the first direction is a direction from the air inlet to the air outlet of the heat-dissipating air duct.

In one implementation, the plurality of heat sinks include a first heat sink and a second heat sink, the first heat sink is disposed on a first surface of the circuit board and corresponds to the heat-generating components, the second heat sink is disposed on a second surface of the circuit board, and along a first direction, the dimension of the first heat sink is the same as the dimension of the second heat sink, wherein the first direction is a direction from an air inlet to the air outlet of the heat-dissipating air duct.

In one implementation, both the first heat sink and the second heat sink include a heat sink body and a plurality of heat sink fins, the density of the heat sink fins of the first heat sink is the same as the density of the heat sink fins of the second heat sink, and the height of the heat sink fins of the first heat sink is different from the height of the heat sink fins of the second heat sink.

In one implementation, both the first heat sink and the second heat sink include a heat sink body and a plurality of heat sink fins, the density of the heat sink fins of the first heat sink is different from the density of the heat sink fins of the second heat sink, and the height of the heat sink fins of the first heat sink is the same as the height of the heat sink fins of the second heat sink.

In one implementation, both the first heat sink and the second heat sink include a heat sink body and a plurality of heat sink fins, and the total surface area of the heat sink fins of the first heat sink is larger than the total surface area of the heat sink fins of the second heat sink.

In one implementation, both the first heat sink and the second heat sink include a heat sink body and a plurality of heat sink fins, and the number of the heat sink fins of the first heat sink is less than the number of the heat sink fins of the second heat sink.

In one implementation, both the first heat sink and the second heat sink include a heat sink body and a plurality of heat sink fins arranged along a second direction, and along the second direction, an end of the second heat sink exceeds a corresponding end of the first heat sink.

In one implementation, the density of the heat-generating components close to an air inlet of the heat-dissipating air duct is greater than the density of the heat-generating components close to the air outlet.

In one implementation, the plurality of the heat-generating components close to the air outlet are divided into a plurality of groups of heat-generating components along a second direction, and the gap between two adjacent groups of heat-generating components is greater than the gap between two adjacent heat-generating components in each group of heat-generating components.

In one implementation, a first connection base and a second connection base are provided at one end of the circuit board in a second direction, and the first connection base and the second connection base are spaced apart in a first direction, wherein the first direction is a direction from an air inlet to the air outlet of the heat-dissipating air duct, and the second direction is perpendicular to the first direction.

In one implementation, both the first connection base and the second connection base include: a connection body connected to a first surface of the circuit board; and an extension portion, one end of which is connected to the connection body, and the other end of which extends away from the circuit board along a third direction, wherein the third direction is perpendicular to the first surface.

In one implementation, an avoidance slot is defined between the extension portion and the first surface.

In one implementation, an edge of the connection body has a flanging extending in a direction away from the circuit board.

In one implementation, the plurality of heat-generating components are provided on a first surface of the circuit board, the heat sink provided on the first surface of the circuit board is a first heat sink, a sealing member is disposed between the first heat sink and the circuit board, and the sealing member is disposed close to an air inlet.

In one implementation, the sealing member includes: a first sealing portion abutting against edges of the circuit board and the first heat sink close to the air inlet; and a second sealing portion disposed on a side surface of the first sealing portion facing away from the air inlet and located in a gap between the first heat sink and the circuit board.

In one implementation, the circuit board and the heat sink are connected by a spring screw, the spring screw includes a screw and a spring sleeved on the screw, and an end of the spring close to the circuit board extends in a direction away from the circuit board.

In one implementation, the direction from an air inlet to the air outlet of the heat-dissipating air duct is a first direction, the heat sink includes a heat sink body and a plurality of heat sink fins, the heat sink body includes a first side surface and a second side surface which are disposed opposite to each other, the circuit board is disposed on the first side surface of the heat sink body, the plurality of heat sink fins are disposed on the second side surface of the heat sink body, and the plurality of heat sink fins are disposed at intervals along a second direction which is perpendicular to the first direction; wherein, along the first direction, an edge of the heat sink body close to the air outlet exceeds the edge of the circuit board close to the air outlet, and/or along the first direction, edges of the heat sink fins close to the air outlet exceed the edge of the circuit board close to the air outlet.

In one implementation, it is suitable for working in the heat-dissipating air duct, wherein the direction from an air inlet to the air outlet of the heat-dissipating air duct is a first direction, the heat sink includes a heat sink body and a plurality of heat sink fins, the heat sink body includes a first side surface and a second side surface which are disposed opposite to each other, the circuit board is disposed on the first side surface, the plurality of heat sink fins are disposed on the second side surface, and the plurality of heat sink fins are disposed at intervals along a second direction which is perpendicular to the first direction; wherein at least one of the heat sink fins is formed with a groove.

In one implementation, the direction from an air inlet to the air outlet of the heat-dissipating air duct is a first direction, wherein the heat sink includes: a first heat sink disposed on a first surface of the circuit board and corresponding to the heat-generating components; and a second heat sink disposed on a second surface of the circuit board, wherein the dimension of the second heat sink is larger than the dimension of the first heat sink.

In one implementation, the direction from an air inlet to the air outlet of the heat-dissipating air duct is a first direction, and the working assembly further includes: a connection base disposed on a first surface of the circuit board and located at the edge of the circuit board.

In one implementation, the heat sink includes: a first heat sink disposed on a first surface of the circuit board; and a screw and a spring configured to connect the circuit board and the first heat sink, wherein a terminal end of the spring close to the first heat sink is disposed away from the first heat sink.

As another aspect of the embodiments of the present application, the present application provides in its embodiments an electronic device including the working assembly according to any one of the above implementations of the present application.

The above summary is for the purpose of illustration only and is not intended to be limiting in any way. In addition to the schematic aspects, implementations and features described above, further aspects, implementations and features of the present application will readily be apparent by referring to the accompanying drawings and the following detailed description.

### BRIEF DESCRIPTION OF THE DRAWINGS

In the drawings, unless otherwise specified, the same reference numerals refer to the same or similar parts or elements throughout the drawings. The drawings are not necessarily drawn to scale. It should be understood that these drawings only depict some implementations disclosed in accordance with the present application and should not be considered as limiting the scope of the present application.

FIG. 1 is a schematic perspective structural diagram of an electronic device according to an embodiment of the present application;

FIG. 2 is a perspective view of the electronic device shown in FIG. 1 from another perspective;

FIG. 3 is a front view of the electronic device shown in FIG. 1;

FIG. 4 is a rear view of the electronic device shown in FIG. 1;

FIG. 5 is a left view of the electronic device shown in FIG. 1;

FIG. 6 is a right view of the electronic device shown in FIG. 1;

FIG. 7 is a top view of the electronic device shown in FIG. 1;

FIG. 8 is a bottom view of the electronic device shown in FIG. 1;

FIG. 9A is an exploded view of the electronic device shown in FIG. 1;

FIG. 9B is an enlarged view of the circled portion A in FIG. 9A;

FIG. 10A is a schematic structural diagram of an air outlet panel according to another embodiment of the present application;

FIG. 10B is a partial enlarged view of the air outlet panel shown in FIG. 10A;

FIG. 11 is another exploded view of the electronic device shown in FIG. 1;

FIG. 12 is a schematic installation diagram of a fan assembly of the electronic device shown in FIG. 1;

FIG. 13 is a sectional view of the electronic device shown in FIG. 1;

FIG. 14 is a schematic diagram of cable connection of a fan module of the electronic device shown in FIG. 1;

FIG. 15 is a perspective view of a fan assembly of the electronic device shown in FIG. 1;

FIG. 16 is an enlarged view of the circled portion B in FIG. 15;

FIG. 17 is a perspective view of a fan assembly of the electronic device shown in FIG. 1 from another perspective;

FIG. 18 is a perspective view of a mounting member of the fan assembly shown in FIG. 17;

FIG. 19 is a perspective view of a flexible protective cover of the fan assembly shown in FIG. 17;

FIG. 20 is a schematic diagram of the internal structure of the electronic device shown in FIG. 1;

FIG. 21 is a schematic diagram of cable connection of the electronic device shown in FIG. 1;

FIG. 22 is a schematic structural diagram of a first conductive connector and a second conductive connector according to an embodiment of the present application;

FIG. 23 is a sectional view of an electronic device according to an embodiment of the present application;

FIG. 24 is an enlarged view of the circled portion C in FIG. 23;

FIG. 25A is a sectional view of an electronic device according to an embodiment of the present application;

FIG. 25B is an enlarged view of the circled portion D in FIG. 25A;

FIG. 26A is a sectional view of an electronic device according to an embodiment of the present application;

FIG. 26B is a partial enlarged view of the electronic device shown in FIG. 26A;

FIG. 27 is a schematic installation diagram of a power module according to an embodiment of the present application;

FIG. 28 is a schematic installation diagram of a power module from another perspective according to an embodiment of the present application;

FIG. 29A is a schematic diagram of the connection between a power module and a housing according to an embodiment of the present application;

FIG. 29B is an enlarged view of the circled portion E in FIG. 29A;

FIG. 30A is a schematic installation diagram of a power module of an electronic device according to another embodiment of the present application;

FIG. 30B is a partial enlarged view of the electronic device shown in FIG. 30A;

FIG. 30C is a schematic structural diagram of a threaded fastener of the electronic device shown in FIG. 30A;

FIG. 31 is a schematic perspective structural diagram of a working assembly according to an embodiment of the present application;

FIG. 32 is a perspective view of the working assembly shown in FIG. 31 from another perspective;

FIG. 33 is a front view of the working assembly shown in FIG. 31;

FIG. 34 is a rear view of the working assembly shown in FIG. 31;

FIG. 35 is a left view of the working assembly shown in FIG. 31;

FIG. 36 is a right view of the working assembly shown in FIG. 31;

FIG. 37 is a top view of the working assembly shown in FIG. 31;

FIG. 38 is a bottom view of the working assembly shown in FIG. 31;

FIG. 39A is an exploded view of the working assembly shown in FIG. 31;

FIG. 39B is a schematic diagram of a working assembly according to another embodiment of the present application;

FIG. 40 is a schematic structural diagram of a first connection base of a working assembly according to an embodiment of the present application;

FIG. 41 is a schematic structural diagram of a first connection base of a working assembly according to an embodiment of the present application;

FIG. 42 is a schematic partial structural diagram of a sealing member of a working assembly according to an embodiment of the present application;

FIG. 43 is a schematic mounting diagram of a sealing member of a working assembly according to an embodiment of the present application;

FIG. 44 is a schematic structural diagram of a spring screw of a working assembly according to an embodiment of the present application;

FIG. 45 is a schematic perspective structural diagram of a working assembly according to another embodiment of the present application;

FIG. 46 is a front view of the working assembly shown in FIG. 45;

FIG. 47 is a rear view of the working assembly shown in FIG. 45;

FIG. 48 is a left view of the working assembly shown in FIG. 45;

FIG. 49 is a right view of the working assembly shown in FIG. 45;

FIG. 50 is a top view of the working assembly shown in FIG. 45;

FIG. 51 is a bottom view of the working assembly shown in FIG. 45; and

FIG. 52 is a schematic structural diagram of a circuit board according to an embodiment of the present application.

### NOTES OF REFERENCE NUMERALS

100: working assembly;
110: circuit board; 111: heat-generating component; 112: first signal socket; 120: heat sink; 121: heat sink body; 122: heat sink fin; 1221: beveled portion; 1222: groove; 123: first heat sink; 124: second heat sink; 140: first connection base; 141: connection body; 1411: flanging; 142: extension portion; 143: avoidance slot; 150: second connection base; 160: sealing member; 161: first scaling portion; 162: second sealing portion; 170: spring screw; 171: spring; 172: screw;
200: electronic device;
210: housing; 211: vent; 212: top housing; 213: air outlet panel; 214: second elastic clip; 215: second conductive foam; 220: fan assembly; 221: mounting member; 2211: threaded hole; 2212: fixing hole; 222: fan module; 230: first elastic clip; 231: connection portion; 232: abutment portion; 240: first conductive foam; 250: flexible protective cover; 260: control board; 261: second signal socket; 262: fan interface; 263: temperature sensor; 264: indicator light; 270: power module; 271: positioning hole; 272: through hole; 273: threaded fastener; 280: first conductive connector; 290: second conductive connector.

### DETAILED DESCRIPTION

Hereinafter, certain exemplary embodiments are described briefly. As those skilled in the art will recognize, the described embodiments may be modified in various ways without departing from the spirit or scope of the present application. Accordingly, the drawings and description are to be regarded as illustrative in nature and not restrictive.

Heat-generating components will generate a lot of heat during operation, so it is necessary to put the circuit board in a heat-dissipating air duct to dissipate heat. However, the temperature difference between the heat-generating components close to the air outlet and the heat-generating components close to the air inlet is usually large, resulting in poor temperature uniformity of the heat-generating components.

By adopting the technical solutions provided herein, the embodiments of the present application can reduce the maximum temperature difference between the heat-generating components close to the air outlet and the heat-generating components close to an air inlet, thereby improving the temperature uniformity of the heat-generating components.

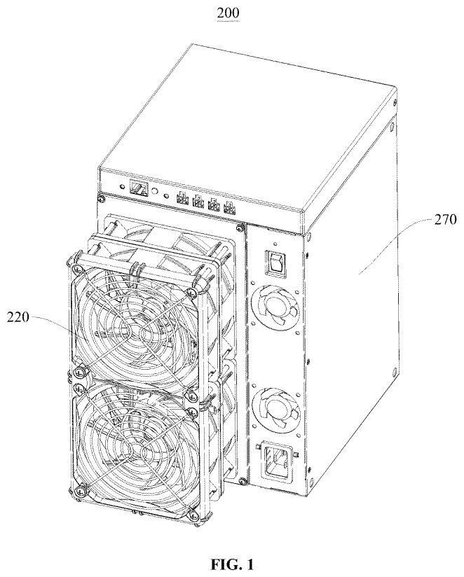

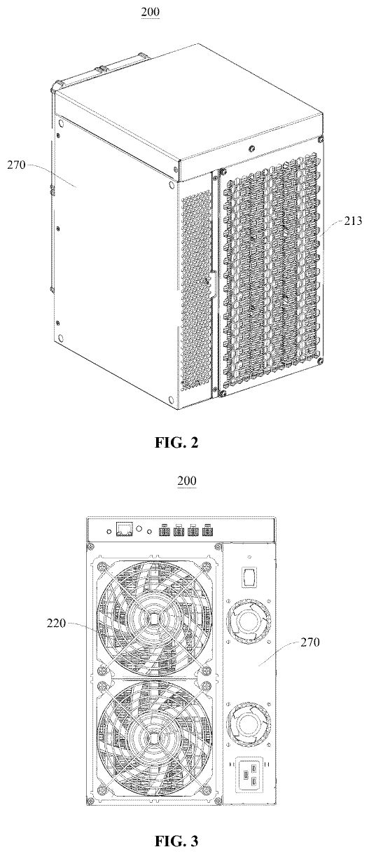

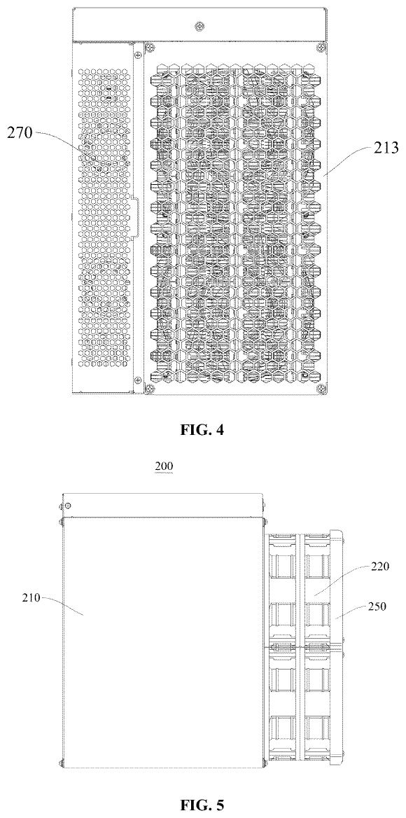

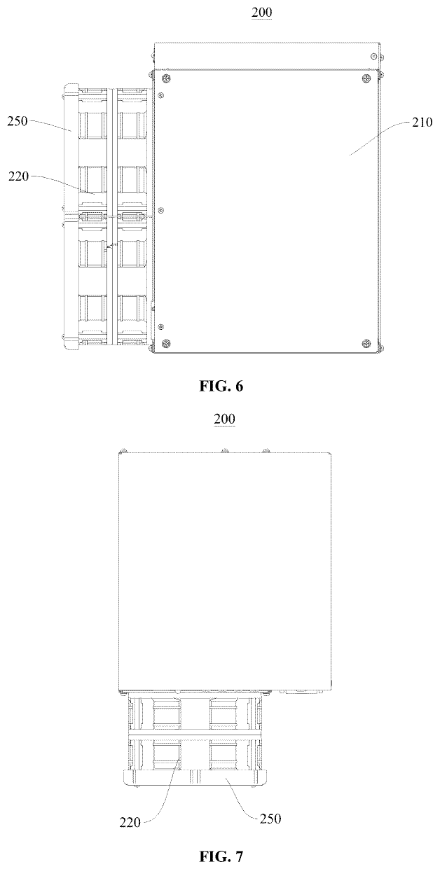

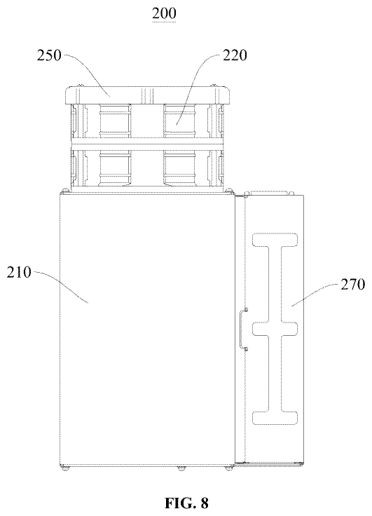

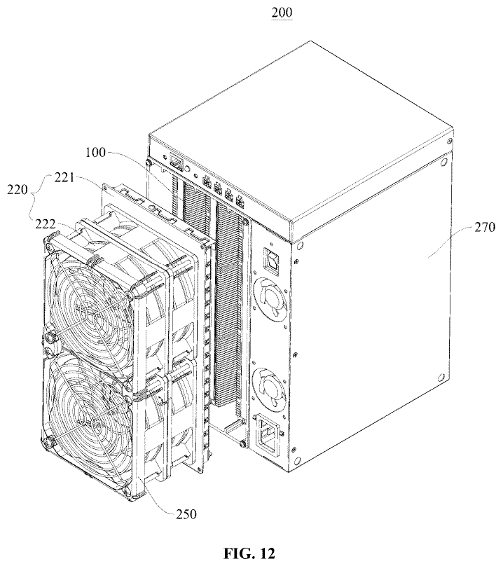

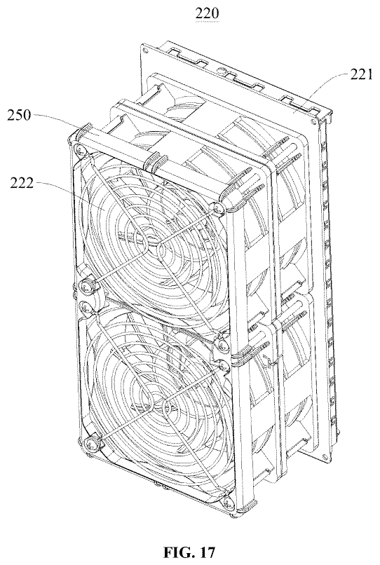

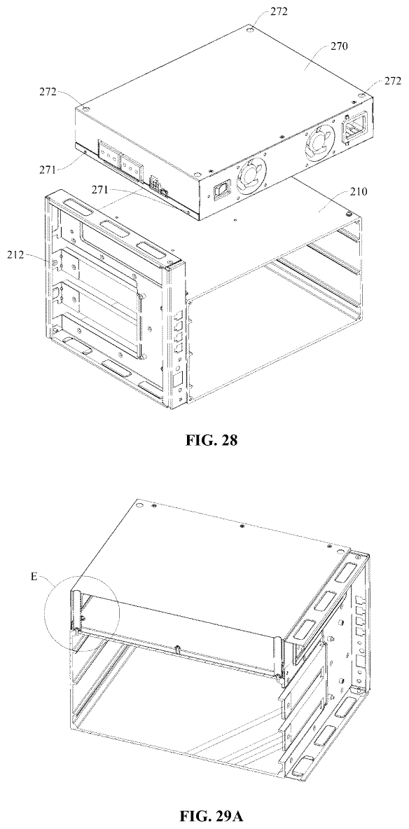

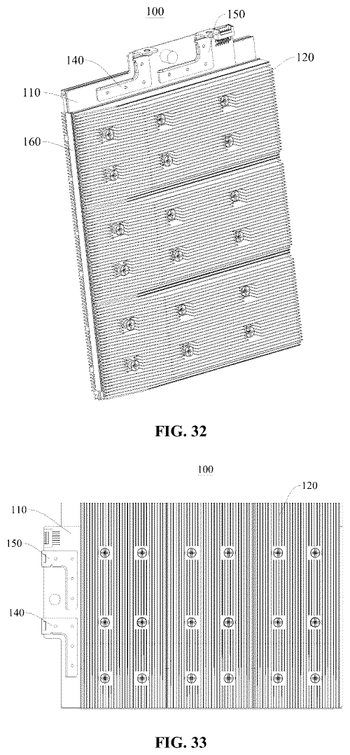

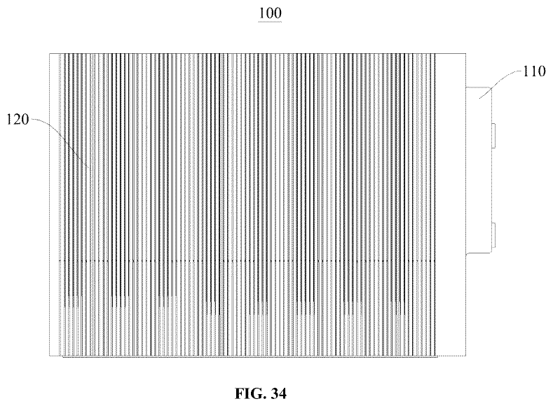

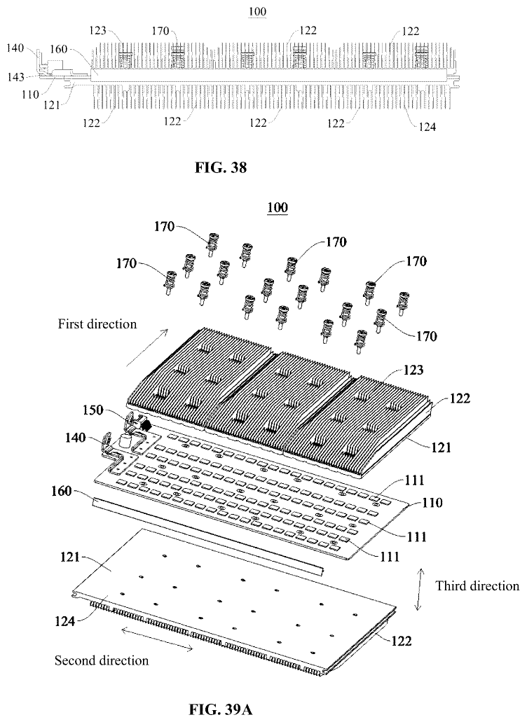

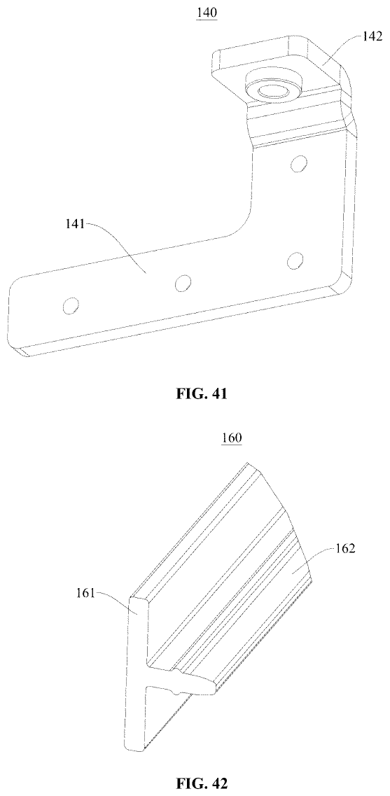

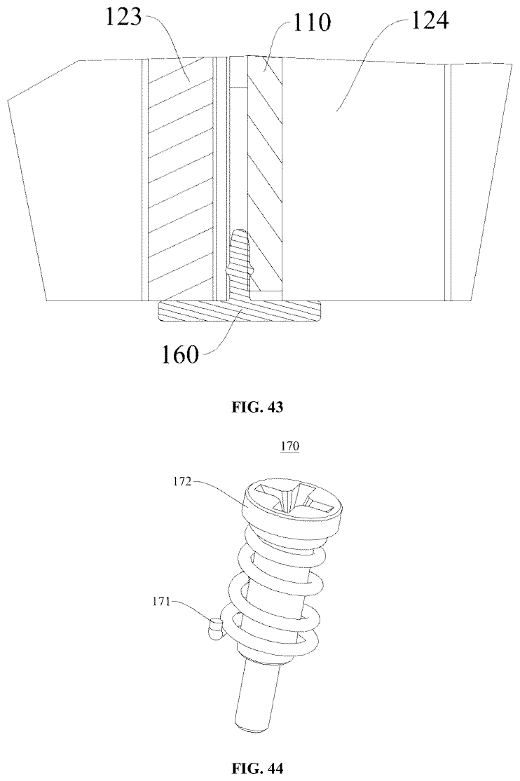

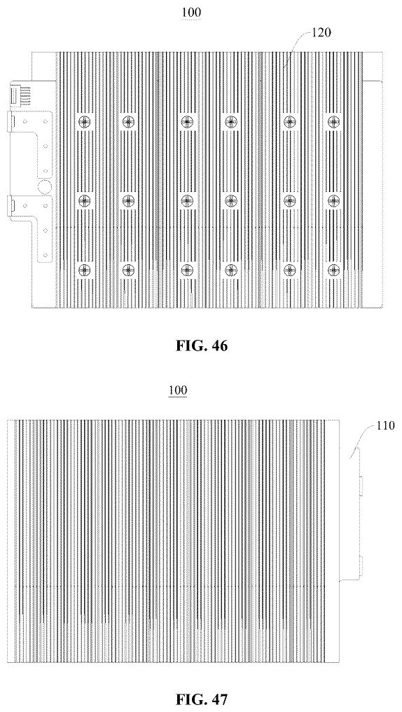

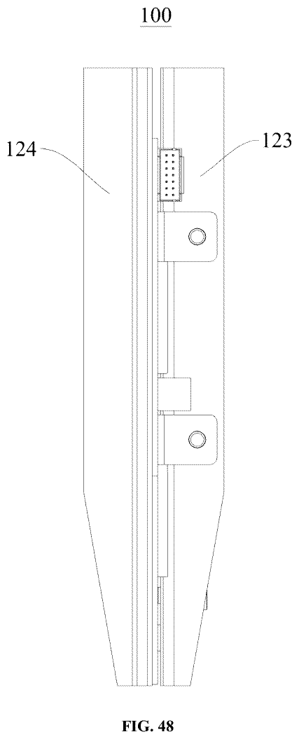

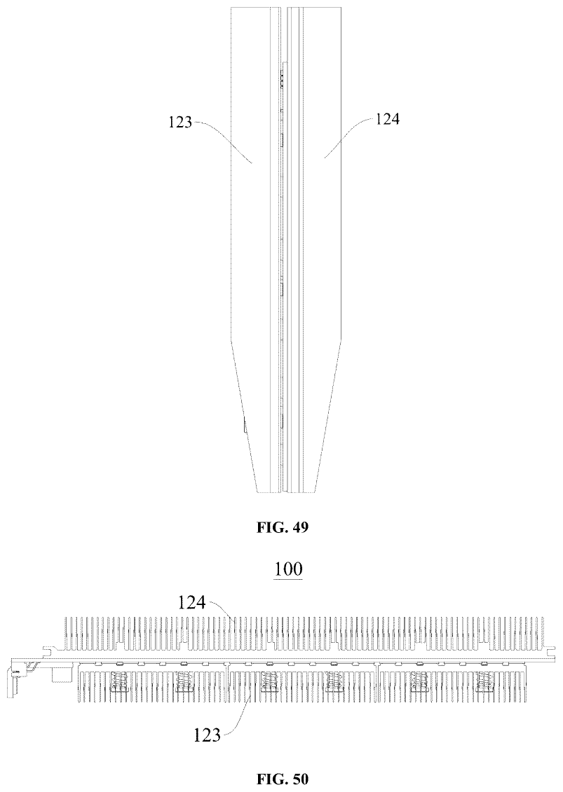

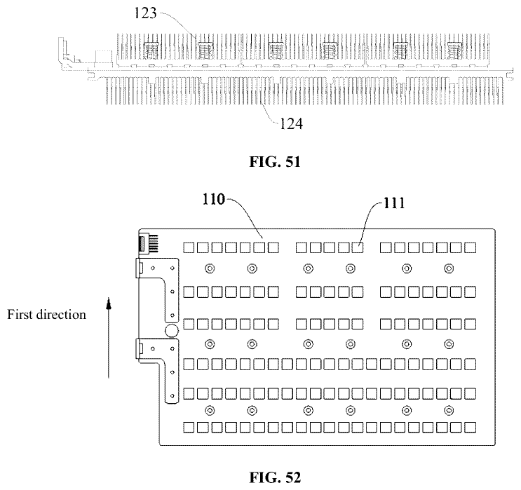

A working assembly 100 according to a first aspect of the embodiments of the present application is described below in conjunction with FIGS. 1-52. The working assembly 100 is suitable for working in a heat-dissipating air duct to achieve heat dissipation of the working assembly 100.

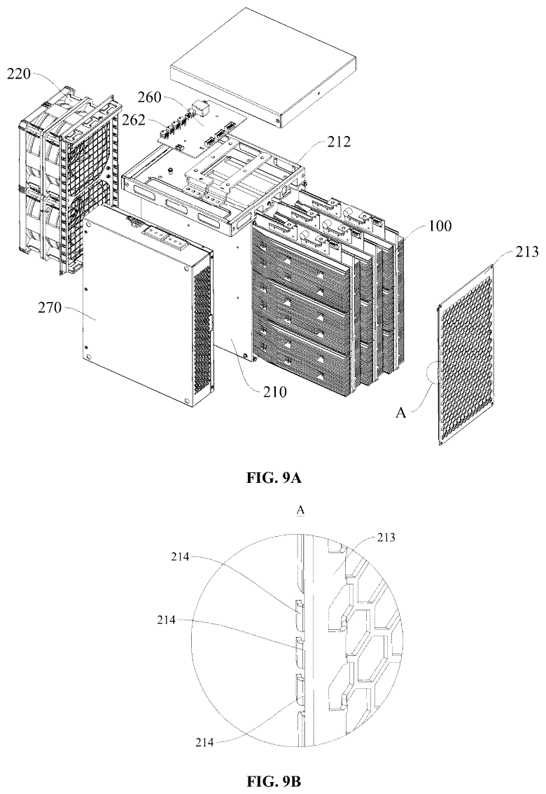

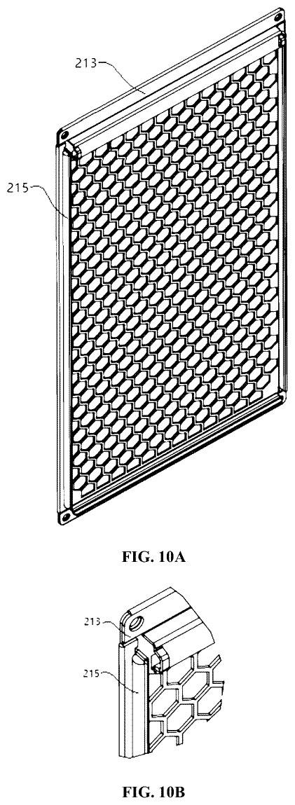

As shown in FIGS. 9 and 31-39A, the working assembly 100 includes a circuit board 110 and at least one heat sink 120. Specifically, a plurality of heat-generating components 111 are disposed on at least one side surface of the circuit board 110, and the heat sink 120 is disposed on the circuit board 110. In the description of the present application, “a plurality of” means two or more.

In one implementation, the direction from an air inlet to the air outlet of the heat-dissipating air duct is a first direction, the heat sink includes a heat sink body and a plurality of heat sink fins, the heat sink body includes a first side surface and a second side surface which are disposed opposite to each other, the circuit board is disposed on the first side surface of the heat sink body, the plurality of heat sink fins are disposed on the second side surface of the heat sink body, and the plurality of heat sink fins are disposed at intervals along a second direction which is perpendicular to the first direction; wherein, along the first direction, an edge of the heat sink body close to the air outlet exceeds the edge of the circuit board close to the air outlet, and/or along the first direction, edges of the heat sink fins close to the air outlet exceed the edge of the circuit board close to the air outlet.

In one implementation, it is suitable for working in the heat-dissipating air duct, wherein the direction from an air inlet to the air outlet of the heat-dissipating air duct is a first direction, the heat sink includes a heat sink body and a plurality of heat sink fins, the heat sink body includes a first side surface and a second side surface which are disposed opposite to each other, the circuit board is disposed on the first side surface, the plurality of heat sink fins are disposed on the second side surface, and the plurality of heat sink fins are disposed at intervals along a second direction which is perpendicular to the first direction; wherein at least one of the heat sink fins is formed with a groove.

In one implementation, the direction from an air inlet to the air outlet of the heat-dissipating air duct is a first direction, wherein the heat sink includes: a first heat sink disposed on a first surface of the circuit board and corresponding to the heat-generating components; and a second heat sink disposed on a second surface of the circuit board, wherein the dimension of the second heat sink is larger than the dimension of the first heat sink.

In one implementation, the direction from an air inlet to the air outlet of the heat-dissipating air duct is a first direction, and the working assembly further includes: a connection base disposed on a first surface of the circuit board and located at the edge of the circuit board.

In one implementation, the heat sink includes: a first heat sink disposed on a first surface of the circuit board; and a screw and a spring configured to connect the circuit board and the first heat sink, wherein a terminal end of the spring close to the first heat sink is disposed away from the first heat sink.

For example, two heat sinks 120 are shown in the examples of FIGS. 31-39A. The two heat sinks 120 are respectively a first heat sink 123 and a second heat sink 124. The first heat sink 123 is disposed on a first surface of the circuit board 110, and the second heat sink 124 is disposed on a second surface of the circuit board 110. The plurality of heat-generating components 111 may include a plurality of chips disposed on the first surface of the circuit board 110. The first heat sink 123 may be disposed corresponding to the chips. The first heat sink 123 may be in contact with the chips directly or indirectly through a thermally conductive material (such as thermal grease). The first heat sink 123 is provided with a plurality of bosses, which are disposed corresponding to the chips. The bosses may be disposed in a plurality of rows or columns, with each row of a plurality of rows of bosses corresponding to each row of chips, and with each column of a plurality of columns of bosses corresponding to each column of chips; the bosses may also be an array of independent structures, with each independent boss corresponding to a single chip, and the cross-sectional area of each independent boss can cover a single chip or be smaller than a single chip. The first heat sink 123 may include a plurality of independently disposed sub-heat sinks.

The heat on the first surface of the circuit board 110 can be effectively conducted to the first heat sink 123, and the heat on the second surface of the circuit board 110 can be effectively conducted to the second heat sink 124. In the process of air blowing from the air inlet to the air outlet of the heat-dissipating air duct, the heat of the first heat sink 123 and the second heat sink 124 can be effectively taken away, thereby achieving effective heat dissipation of the circuit board 110.

Although two heat sinks 120 are shown in FIGS. 31-39A for illustrative purposes, after reading the technical solution of the present application, a person of ordinary skill in the art would clearly understand that the solution can be applied to technical solutions involving one heat sink or more than two heat sinks 120, and such applications also fall within the scope of protection of the present application.

At the air outlet of the heat-dissipating air duct, the dimension of at least one heat sink 120 in the first direction is larger than the dimension of the circuit board 110 in the first direction, and the first direction is a direction from the air inlet to the air outlet of the heat-dissipating air duct. An edge of at least one heat sink 120 close to the air outlet exceeds an edge of the circuit board 110 close to the air outlet.

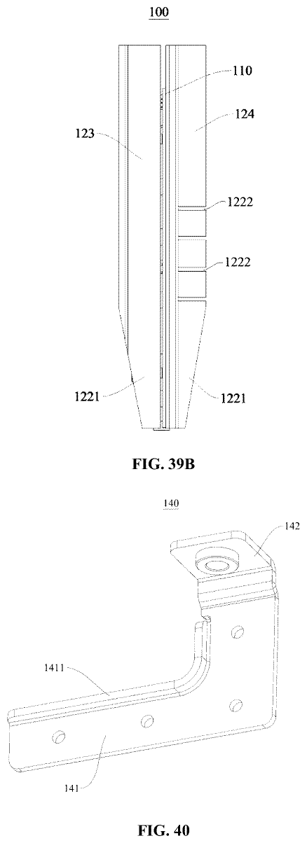

Illustratively, the first and second surface of the circuit board 110 may both be parallel to the first direction. The plurality of heat-generating components 111 on the first surface may be disposed in a row, and in the second direction, the centers of at least three or all of the heat-generating components 111 are in a straight line, and the second direction is perpendicular to the first direction. FIG. 39A shows six columns of heat-generating components 111. The six columns of heat-generating components 111 can be divided into two parts, and each part includes three columns of heat-generating components 111. One of the two parts is disposed close to the air inlet, and the other of the two parts is disposed close to the air outlet. The edges of the first heat sink 123 and the second heat sink 124 close to the air outlet may both extend beyond the edge of the circuit board 110 close to the air outlet. With such a configuration, it may increase the area of the heat sink 120 at the air outlet, so that the heat of a group of heat-generating components 111 close to the air outlet can be better conducted to the corresponding heat sink 120, reducing the maximum temperature difference between the three rows of heat-generating components 111 close to the air outlet. At the same time, the heat dissipation effect of the three rows of heat-generating components 111 close to the air outlet can be improved, which is beneficial to reducing the maximum temperature difference between the two groups of heat-generating components 111, thereby improving the overall temperature uniformity of the plurality of heat-generating components 111.

The working assembly 100 according to the embodiments of the present application may lengthen the dimension of the at least one heat sink 120 close to the air outlet in the first direction, thereby reducing the maximum temperature difference between the heat-generating components 111 close to the air outlet and the heat-generating components 111 close to the air inlet, thereby improving the temperature uniformity of the heat-generating components 111.

In one implementation, along the first direction, the dimension of the heat sink 120 exceeds the dimension of the circuit board 110 by 10 mm to 20 mm (inclusive). Specifically, for example, the dimension of the heat sink 120 exceeds the dimension of the circuit board 110 by L. When L is less than 10 mm, at the air outlet of the heat-dissipating air duct, the dimension of the heat sink 120 exceeding the circuit board 110 in the first direction is too small, resulting in poor heat dissipation effect of the heat-generating components 111 close to the air outlet, and the temperature uniformity of the heat-generating components 111 cannot be effectively improved; when L is greater than 20 mm, the dimension of the heat sink 120 exceeding the circuit board 110 in the first direction is too large, and the space occupied by the heat sink 120 at the air outlet is too large, which will increase the volume of the housing 210 and cause the weight of the heat sink 120 to be too heavy.

Therefore, by ensuring that 10 mm≤L≤20 mm, the dimension of the portion of the heat sink 120 exceeding the end of the circuit board 110 close to the air outlet is reasonable, which can effectively improve the temperature uniformity of the heat-generating components 111 while reducing the overall space occupied by the working assembly 100, and avoid excessive weight of the working assembly 100. Optionally, L may be 15 mm, but is not limited thereto. Those skilled in the art will understand that “the dimension of the heat sink 120 exceeds the dimension of the circuit board 110 by L”, and L is not limited to the above range of 10 mm≤L≤20 mm. When there is a need to improve the heat dissipation of the rear half of the circuit board or the heat-generating source, the method of extending the length of the heat sink in the present invention can be applied to adaptively adjust the length L according to different usage scenarios.

In one implementation, in combination with FIGS. 39A and 39B, each heat sink 120 includes a heat sink body 121 and a plurality of heat sink fins 122 disposed on the heat sink body 121, the heat sink body 121 is parallel to the circuit board 110, the heat sink fins 122 are perpendicular to the circuit board 110, and at least one of heat sink fins 122 is formed with at least one groove 1222.

In an example, each groove 1222 may penetrate a corresponding heat sink fin 122 in the second direction and a third direction to divide the heat sink fin 122 into a plurality of sub-heat sink fins. The calculation formula of the convection thermal resistance between the heat sink fin 122 and the air environment is: R=1/(hA), where R is the convection thermal resistance between the heat sink fin and the air environment, h is the convection heat transfer coefficient, and A is the heat dissipation area. The groove 1222 can divide the entire heat sink 122 into a plurality of sub-heat sinks spaced apart in the first direction. The air will expand and then contract before and after flowing through this area. After the air passes through the groove 1222 area, the disturbance becomes stronger, the convection heat transfer coefficient becomes larger, and the thermal resistance is reduced.

In an example, at least one groove 1222 does not penetrate the corresponding heat sink fin 122 in the second direction and/or the third direction. At this time, the heat sink fin 122 is not divided into a plurality of sub-fins. The second direction is a direction in which the plurality of heat sink fins 122 are arranged, and the third direction is a direction perpendicular to the surface of the circuit board 110.

Therefore, by disposing the above-mentioned groove 1222, the overall weight of the heat sink 122 can be reduced, and the air resistance of air flowing through the heat sink 120 can be effectively reduced, the ventilation volume can be increased, and the dust accumulation on the heat sink 122 can be reduced while improving the heat-dissipation effect. Specifically, the amount of dust accumulated on the side of the heat sink 120 close to the air inlet is generally greater than the amount of dust accumulated on the side close to the air outlet. In the case where the groove 1222 is disposed at an end of the heat sink fin 122 close to the air inlet, the amount of dust accumulated at the end of the heat sink 120 close to the air inlet may be further increased. By disposing the groove 1222 at an end of the heat sink fin 122 close to the air outlet, it is possible to avoid increasing the amount of dust accumulation at the air inlet of the heat sink 120 and improve the local heat dissipation effect of the heat sink 120.

In one implementation, the groove 1222 is disposed at an end of the heat sink 122 closer to the air outlet relative to the center of the heat sink 120, that is, “the end closer to the air outlet” refers to the end closer to the air outlet with the center of the heat sink 120 as a reference standard. Therefore, since the temperature of the air at the air outlet is usually high, after the air exchanges heat with the end of the heat sink 120 close to the air outlet, the heat generated by the heat-generating components 111 during operation cannot be effectively taken away. By disposing the groove 1222 close to the air outlet, the convection heat transfer coefficient of the air outlet area can be increased, and the thermal resistance at the air outlet can be reduced, thereby increasing the ventilation volume at the air outlet, improving the heat dissipation effect of the heat-generating components 111 at the air outlet, while also suppressing the deposition of dust, further improving the temperature uniformity of the heat-generating components 111.

In one implementation, the groove 1222 is disposed corresponding to the heat-generating components 111. Illustratively, the heat sink fins 122 of the at least one heat sink 120 are all provided with a groove 1222, a plurality of grooves 1222 are disposed in a row, and at least one row of grooves 1222 is disposed opposite to at least one row of heat-generating components 111. For example, the grooves 1222 on the plurality of heat sink fins 122 may correspond to each other in the direction in which the heat sink fins 122 are arranged, so that the grooves 1222 on the plurality of heat sink fins 122 are disposed in a row. It is possible that only the heat sink fins 122 of the first heat sink 123 are provided with grooves 1222, as shown in FIG. 39B; or only the heat sink fins 122 of the second heat sink 124 are provided with grooves 1222; and it is also possible that both the heat sink fins 122 of the first heat sink 123 and the second heat sink 124 are provided with grooves 1222, in which case the grooves 1222 on the heat sink fins 122 on the first heat sink 123 and the second heat sink 124 may be different.

Optionally, the dimension of the groove 1222 in the first direction may be 2.5 mm to 3.5 mm (inclusive). However, it is not limited to this range. For example, when the dimension of the groove 1222 in the first direction is less than 2.5 mm, the width of the groove 1222 is too small, which may reduce the weight reduction effect; when the dimension of the groove 1222 in the first direction is greater than 3.5 mm, the width of the groove 1222 is too large, which may cause the surface area of the heat sink 122 to be too small, thereby reducing the heat dissipation effect. By enabling the dimension of the groove 1222 in the first direction to be 2.5 mm to 3.5 mm, the weight of the heat sink 120 can be effectively reduced while ensuring the heat dissipation effect of the heat sink 120.

Illustratively, along the first direction, the dimension of the groove 1222 on the heat sink fin 122 may gradually increase; or along the first direction, the dimension of the groove 1222 on the heat sink fin 122 may gradually decrease; or along the first direction, the dimension of the groove 1222 on the heat sink fin 122 may be completely equal. It is also possible that the dimension of the groove 1222 is positively or negatively correlated with the width of the heat sink fin 122. Of course, the present application is not limited thereto. For example, the dimension of the groove 1222 on the heat sink fin 122 can be set as needed, and at the same time, the width of the heat sink fin between two grooves 1222 can be changed in combination. It will be understood that the dimension, number, and specific position of the grooves 1222 on the heat sink fins 122 can be specifically set according to actual needs to better meet practical applications.

Therefore, by making the grooves 1222 correspond to the heat-generating components 111 in position, the heat generated during operation by the heat-generating components 111 opposite to the grooves 1222 can be conducted to the heat sink body 121, and the air flowing through the heat sink body 121 can directly exchange heat with the heat sink body 121 to achieve heat dissipation of the heat-generating components 111. Since the convection heat transfer coefficient at the groove 1222 is large, the air resistance can be effectively reduced, thereby increasing the air volume at the heat-generating components 111 opposite to the grooves 1222 and improving the heat dissipation effect of the heat-generating components 111 opposite to the grooves 1222.

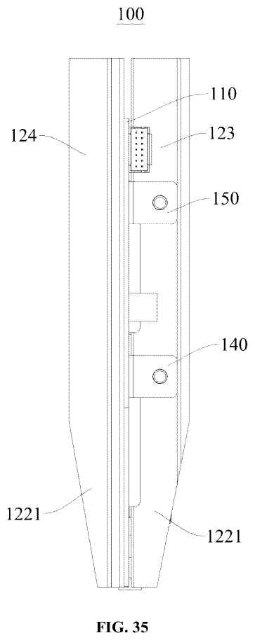

In one implementation, in combination with FIGS. 35, 36 and 39A, the at least one heat sink fin 122 includes a beveled portion 1221, and a height of the beveled portion 1221 gradually increases along the first direction.

In one implementation, an end of the beveled portion 1221 that is away from the air inlet corresponds to the position of a third column of heat-generating components 111. The above-mentioned “third column of heat-generating components 111” refer to the heat-dissipating components located in the third column along the first direction. For example, in the examples of FIGS. 35, 36 and 39A, all the heat sink fins 122 of the first heat sink 123 and the second heat sink 124 include a beveled portion 1221, and the beveled portion 1221 is disposed close to the air inlet. Six columns of heat-generating components 111 are disposed on the circuit board 110. Along the first direction, the first three columns of heat-generating components 111 may be disposed opposite to the beveled portion 1221, and the last three columns of heat-generating components 111 may be disposed opposite to the corresponding grooves 1222.

Therefore, by disposing the above-mentioned beveled portion 1221, the weight of the entire heat sink fin 122 can be effectively reduced, and the thermal resistance at the air inlet can be reduced, thereby increasing the ventilation volume at the air inlet, and improving the heat dissipation effect of the heat-generating components 111 at the air inlet, while also suppressing the deposition of dust and improving the temperature uniformity of the heat-generating components 111.

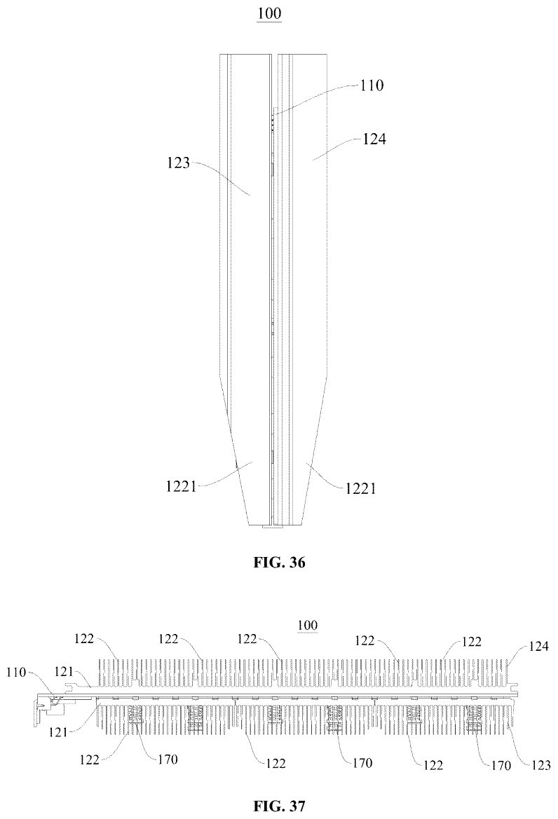

In one implementation, as shown in FIGS. 35 and 36, along the first direction, the dimension of the first heat sink 123 is the same as the dimension of the second heat sink 124. With such a configuration, while achieving heat dissipation of the first surface and the second surface of the circuit board 110, the dimensions of the first heat sink 123 and the second heat sink 124 may be consistent, thereby improving the versatility of the heat sink 120 and facilitating the processing of the heat sink 120.

In one implementation, the density of the heat sink fins 122 of the first heat sink 123 is the same as the density of the heat sink fins 122 of the second heat sink 124, and the height of the heat sink fins 122 of the first heat sink 123 is different from the height of the heat sink fins 122 of the second heat sink 124. For example, the height of the heat sink fins 122 of the first heat sink 123 may be greater than the height of the heat sink fins 122 of the second heat sink 124. Since the first heat sink 123 is in contact with a plurality of heat-generating components 111, by making the height of the heat-generating fins 122 of the first heat sink 123 greater than the height of the heat-generating fins 122 of the second heat sink 124, the area of the heat-generating fins 122 of the first heat sink 123 can be greater than the area of the heat-generating fins 122 of the second heat sink 124. Thus, the heat-generating fins 122 of the first heat sink 123 can effectively absorb the heat generated by the plurality of heat-generating components 111 during operation, thereby improving the heat dissipation effect.

In one implementation, the height of the heat sink fins 122 of the first heat sink 123 is the same as the height of the heat sink fins 122 of the second heat sink 124, and the density of the heat sink fins 122 of the first heat sink 123 is different from the density of the heat sink fins 122 of the second heat sink 124. For example, the density of the heat sink fins 122 of the first heat sink 123 may be greater than the density of the heat sink fins 122 of the second heat sink 124. Since the first heat sink 123 is in contact with a plurality of heat-generating components 111, by making the density of the heat sink fins 122 of the first heat sink 123 greater than the density of the heat sink fins 122 of the second heat sink 124, the area of the heat sink fins 122 of the first heat sink 123 can be greater than the area of the heat sink fins 122 of the second heat sink 124. Thus, the heat sink fins 122 of the first heat sink 123 can also effectively absorb the heat generated by the plurality of heat-generating components 111 during operation, which is beneficial to improving the heat dissipation effect. Or the density of the heat sink fins 122 of the first heat sink 123 may be less than the density of the heat sink fins 122 of the second heat sink 124, so that there is more heat dissipating space between adjacent heat sink fins 122 of the first heat sink 123, and the first heat sink 123 shares more air, thereby reducing air resistance, increasing ventilation, and improving dust deposition. This can also effectively dissipate heat generated during the working process of the plurality of heat-generating components 111.

In an optional implementation, the total surface area of the heat sink fins 122 of the first heat sink 123 is larger than the total surface area of the heat sink fins 122 of the second heat sink 124. This is beneficial for lowering the overall temperature of the plurality of heat-generating components 111, while lowering the maximum temperature of the plurality of heat-generating components 111.

Of course, the present application is not limited to the above. In another optional implementation, the total surface area of the heat sink fins 122 of the first heat sink 123 may be less than the total surface area of the heat sink fins 122 of the second heat sink 124. In this way, the amount of dust accumulation of the first heat sink 123 can be further reduced, and the heat generated by the plurality of heat-generating components 111 during operation can be effectively dissipated.

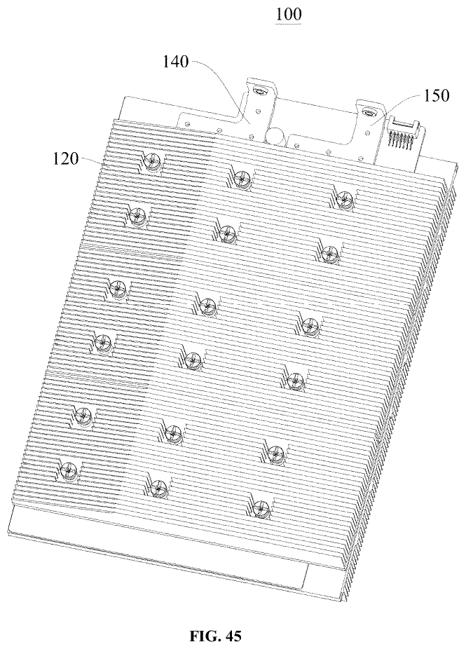

In one implementation, as shown in FIGS. 45-51, the number of heat sink fins 122 of the first heat sink 123 may be less than the number of heat sink fins 122 of the second heat sink 124. In this way, the total surface area of the heat sink fins 122 of the first heat sink 123 can be relatively small, thereby increasing the ventilation volume and reducing dust accumulation. This also can effectively dissipate the heat generated by the plurality of heat-generating components 111 during operation.

In one implementation, with reference to FIGS. 45-51, along the second direction, an end of the second heat sink 124 exceeds a corresponding end of the first heat sink 123. For example, in the examples of FIGS. 45 to 51, along the second direction, the dimension of the second heat sink 124 is larger than the dimension of the first heat sink 123, and both ends of the second heat sink 124 exceed corresponding ends of the first heat sink. With such a configuration, the number of heat sink fins 122 of the second heat sink 124 is relatively large, and the total surface area of its heat sink fins 122 is relatively large. The heat generated during operation of the circuit board 110 can be effectively discharged through the heat sink fins 122 of the second heat sink 124. At the same time, the number of the first heat sink 123 can be relatively small, and the total surface area of its heat sink fins 122 is relatively small, which can further improve the problem of serious dust accumulation on the first heat sink 123, increase the ventilation volume of the first heat sink 123, and further improve the heat dissipation effect.

In one implementation, the density of the heat-generating components 111 close to an air inlet of the heat-dissipating air duct is greater than the density of the heat-generating components 111 close to the air outlet. Since the air entering from the air inlet is cold air and the air exiting from the air outlet is hot air, the heat generated by the heat-generating components 111 at the air inlet can be increased by increasing the density of the heat-generating components 111 at the air inlet, and the heat generated by the heat-generating components 111 at the air outlet can be reduced by reducing the density of the heat-generating components 111 at the air outlet, thereby further reducing the maximum temperature difference between the heat-generating components 111 close to the air outlet and the heat-generating components 111 close to the air inlet and improving the temperature uniformity of the heat-generating components 111.

In one implementation, as shown in FIG. 52, the plurality of the heat-generating components 111 close to the air outlet are divided into a plurality of groups of heat-generating components along the second direction, and the gap between two adjacent groups of heat-generating components is greater than the gap between two adjacent heat-generating components 111 in each group of heat-generating components.

For example, six columns of heat-generating components 111 are shown in the example of FIG. 52. For the convenience of description, the six columns of heat-generating components 111 sequentially arranged along the first direction are respectively referred to as the first heat-generating column, the second heat-generating column, . . . , the sixth heat-generating column. There are 21 heat-generating components 111 in the first to third heat-generating columns, and there are 19 heat-generating components 111 in the fourth to sixth heat-generating columns. The 21 heat-generating components 111 in the first to the third heat-generating columns are evenly spaced. The 19 heat-generating components 111 in the fourth to sixth heat-generating columns are divided into three groups of heat-generating components, and the number of heat-generating components 111 in the groups of heat-generating components located at two ends of the second direction among the three groups of heat-generating components is the same, and the number of heat-generating components 111 in the group of heat-generating components located in the middle of the second direction is less than the number of heat-generating components 111 in the groups of heat-generating components at the two ends.

In this embodiment, there may be a larger heat dissipation gap between two adjacent groups of heat-generating components at the air outlet, which may reduce the temperature near the air outlet and further reduce the maximum temperature difference between the air inlet and the air outlet, thereby improving the temperature uniformity of the working assembly 100.

In one implementation, the heat-generating components 111 may be arranged in various forms, such as in chip arrays. From the first column close to the air inlet (such as the first heat-generating column mentioned above) to the last column close to the air outlet (such as the sixth heat-generating column mentioned above), the number of chips in each column is not completely equal. The number of chips in each column can be gradually decreased, for example, 21, 20, 19, 18, 17, 16; it can be partially decreased, for example, 21, 21, 21, 19, 19, 19; it can also be a jump in number, for example, 21, 21, 20, 19, 20, 21; or 21, 21, 20, 19, 18, 21; and other numbers of chip arrays can also be set according to heat dissipation requirements, so that the total number of chips in the front half close to the air inlet is greater than the total number of chips in the back half close to the air outlet. The front half and the back half here can be divided in half in terms of the number of chip columns, or in half in terms of the dimension of the circuit board 110. As shown in FIG. 52, the total number of chips in the first three columns close to the air inlet is set to be greater than the total number of chips in the last three rows close to the air outlet.

Due to the change in the number of chips in each column, the arrangement of the chips in each row may also be combined in different forms, and the number of chips in each row may be different. For example, some rows of chips are arranged in a straight line with the center points of the chips, while the center points of some rows of chips do not form a straight line, such as in a stepped arrangement (for example, in line with the above “the number of chips in each column gradually decreases, for example, 21, 20, 19, 18, 17, 16”, the row direction presents a stepped arrangement). There are also different embodiments for the number of chips in each row. For example, in the second direction, the number of chips in the rows close to the two ends of the circuit board 110 is greater than the number of chips in the row close to the center of the circuit board 110. In short, the total chip distribution and/or quantity is divided, and the total number of chips in each part meets the preset distribution requirements.

Specifically, in the second direction, the circuit board 110 is divided into three parts from left to right based on the number of chips in the first heat-generating column, namely, the first part, the second part and the third part. The total number of chips in the first part or the third part close to the two ends of the circuit board 110 is greater than the number of chips in the second part in the middle. In another embodiment, if the circuit board 110 is divided into two parts from left to right in the second direction based on the number of chips in the first heat-generating column, the number of chips in the first part is less than or equal to the number of chips in the second part.

With reference to FIG. 52, the above-mentioned specific division is based on the number of chips in the first heat-generating column in the second direction. In one embodiment, it is divided by way of average division. The circuit board 110 is divided into three parts from left to right. There are 21 chips in the first heat-generating column. The circuit board 110 is divided into three parts from left to right. Each 7 chips in the first heat-generating column are divided into a part accordingly. Then, the total number of chips in the first part is 42, the total number of chips in the second part is 36, and the total number of chips in the third part is 42. The total number of chips in the first part (i.e., 42) or the third part (i.e., 42) close to the two ends of the circuit board 110 is greater than the number of chips in the middle second part (i.e., 36). If in the second direction, the circuit board 110 is divided into two parts from left to right based on the number of chips in the first heat-generating column, the circuit board 110 can be divided into two parts from left to right with the center axis of the 11th chip in the middle of the first heat-generating column as the dividing point, and then the number of chips in the first part (i.e., 57) is equal to the number of chips in the second part (i.e., 57). Those skilled in the art will understand that the way of division is not limited to the ways described above, and when the total number of chips in the first heat-generating column is an odd number or an even number, the way of division can be flexibly selected. Of course, the overall area formed by the edges of the chips disposed on the circuit board can be used as a reference for segmentation and division. The area can be evenly divided, or divided according to other proportions, so that the total number of chips in each part meets the preset distribution requirements.

In short, the arrangement of the chips can be set according to the heat dissipation conditions at various positions in the air duct. For example, if the ambient temperature at the air inlet is low and the overall heat dissipating efficiency is high, more chips can be arranged; and if the ambient temperature at the air outlet is high and the overall heat dissipating efficiency is low, fewer chips can be arranged, and the total number of chips close to the air outlet is less than the total number of chips close to the air inlet. At the same time, the temperatures at the upper and lower ends of the circuit board 110 in the direction perpendicular to the air direction are lower than the temperature at the center of the circuit board 110. In this case, more chips can be arranged at the two ends and fewer chips can be arranged at the center. The total number of chips at the two ends is greater than the total number of chips in the center. Alternatively, after being divided into two parts, the total number of chips in the lower half can be greater than the total number of chips in the upper half. This is a completely different design idea from conventionally changing the thermal resistance of the heat sink to achieve uniform temperature.

In one implementation, with reference to FIGS. 31 and 39A-42, a first connection base 140 and a second connection base 150 are provided at an end of the circuit board 110 in the second direction, and the first connection base 140 and the second connection base 150 are spaced apart in the first direction, wherein the second direction is perpendicular to the first direction. For example, the first connection base 140 and the second connection base 150 may be aluminum bases or copper bases. The thickness of the connection base when it is made of aluminum may be greater than when it is made of copper. Therefore, by disposing the first connection base 140 and the second connection base 150, compared with the way of disposing a plurality of connecting plates in the prior art, the first connection base 140 and the second connection base 150 are simpler in structure and easier to process, which can effectively improve the assembly efficiency of the working assembly 100.

Further, as shown in FIGS. 39A-42, both the first connection base 140 and the second connection base 150 include a connection body 141 and an extension portion 142. The connection body 141 is connected to the first surface of the circuit board 110, one end of the extending portion 142 is connected to the connection body 141, and the other end of the extending portion 142 extends away from the circuit board 110 along a third direction, wherein the third direction is perpendicular to the first surface. For example, the extension portion 142 may include a first connecting segment, a second connecting segment, and a third connecting segment. One end of the first connecting segment may be connected to the connection body 141, and the other end of the first connecting segment may be obliquely arranged in the direction away from the circuit board 110. One end of the second connecting segment may be connected to the other end of the first connecting segment, and the second connecting segment may be disposed away from the first connecting segment in a direction parallel to the first surface. One end of the third connecting segment may be connected to the other end of the second connecting segment, and the other end of the third connecting segment may be disposed away from the circuit board 110 in a direction perpendicular to the first surface.

Therefore, by disposing the above-mentioned connection body 141 and extension portion 142, a firm connection between the entire connection base (that is, the above-mentioned first connection base 140 and the second connection base 150) and the circuit board 110 can be achieved through the connection body 141, and the extension portion 142 can extend outward to connect with the conductive connecting part, thereby realizing power supply for the circuit board 110.

In one implementation, an avoidance slot 143 is defined between the extension portion 142 and the first surface. For example, the avoidance slot 143 is co-defined by the first connecting segment, the second connecting segment and the first surface of the circuit board 110. In this way, the wiring harness can pass through the avoidance slot 143, thereby effectively playing the role of avoidance routing.

In one implementation, as shown in FIG. 40, the edge of the connection body 141 has a flanging 1411 extending in a direction away from the circuit board 110. With such a configuration, the flanging 1411 may effectively resist bending, so as to ensure the connection between the connection body 141 and the circuit board 110 to be more secure, preventing the edge of the connection body 141 from warping, and improving reliability.

In one implementation, with reference to FIGS. 39A, 42 and 43, a plurality of heat-generating components 111 are disposed on the first surface of the circuit board 110, a sealing member 160 is disposed between the first heat sink 123 and the circuit board 110, and the sealing member 160 is disposed close to the air inlet. For example, the sealing member 160 may be a rubber member. Therefore, by disposing the above-mentioned sealing member 160, the sealing performance between the first heat sink 123 and the circuit board 110 at the air inlet can be improved to prevent moisture from entering through the gap between the first heat sink 123 and the circuit board 110, thereby protecting the heat-generating components 111 close to the air inlet and meanwhile preventing air leakage.

In one implementation, with reference to FIGS. 39A, 42 and 43, the sealing member 160 includes a first sealing portion 161 and a second sealing portion 162. The first sealing portion 161 abuts against the edge of the circuit board 110 and the first heat sink 123 close to the air inlet, and the second sealing portion 162 is disposed on a side surface of the first sealing portion 161 away from the air inlet, and the second sealing portion 162 is located in a gap between the first heat sink 123 and the circuit board 110. Illustratively, the second sealing portion 162 divides the first scaling portion 161 into two parts, one of which contacts at least an edge of the heat sink body 121 of the first heat sink 123, and the other of which contacts at least an edge of the circuit board 110. There is an inlet between the edge of the heat sink body 121 of the first heat sink 123 close to the air inlet and the edge of the circuit board 110 close to the air inlet, and the second sealing portion 162 extends into the gap between the first heat sink 123 and the circuit board 110 through the inlet.

Therefore, by arranging the first sealing portion 161 and the second sealing portion 162 described above, the first sealing portion 161 has a better shielding effect, preventing moisture at the air inlet from directly contacting the heat sink body 121 of the first heat sink 123 or the circuit board 110, and the second sealing portion 162 has an effective sealing effect, further preventing moisture from entering the gap between the first heat sink 123 and the circuit board 110, thereby further improving the sealing of the first heat sink 123 and the circuit board 110 at the air inlet.

In one implementation, in conjunction with FIGS. 45-51, the working assembly 100 may not be provided with the sealing member 160, thereby ensuring the heat dissipation performance of the entire working assembly 100.

In one implementation, as shown in FIG. 39A and 44, the circuit board 110 and the heat sink 120 may be connected via a connector. For example, the connector may be a screw, an clastic connector, or the like.

In one implementation, as shown in FIGS. 39A and 44, the circuit board 110 and the heat sink 120 are connected by a spring screw 170, and the spring screw 170 includes a screw 172 and a spring 171 sleeved on the screw 172, and the end of the spring 171 close to the circuit board 110 extends in a direction away from the circuit board 110. For example, in the examples of FIGS. 39A and 44, the tail of the spring 171 is folded in the direction away from the circuit board 110. Therefore, although the spring 171 has a sharp end, the above-mentioned arrangement can prevent the end of the spring 171 from scraping aluminum chips due to the contact between the end of the spring 171 and the surface of the circuit board 110, thereby avoiding damage to the circuit board 110 and improving the integrity and reliability of the circuit board 110.

An electronic device 200 according to an embodiment of the second aspect of the present application, such as a computing device, as shown in FIGS. 1-9A, includes the working assembly 100 according to any one of the implementations of the first aspect of the present application.

By adopting the working assembly 100 described above, the electronic device 200 according to the embodiments of the present application, such as a computing device, can reduce the maximum temperature difference between the heat-generating components 111 close to the air outlet and the heat-generating components 111 close to the air inlet, thereby improving the temperature uniformity of the heat-generating components 111.

In one implementation, with reference to FIGS. 1-9A, the electronic device 200 includes a housing 210 and a fan assembly 220. A heat-dissipating air duct having an air inlet and an air outlet is defined in the housing 210, and at least one working assembly 100 is disposed in the heat-dissipating air duct. The working assembly 100 includes a circuit board 110 and a plurality of heat sinks 120. The plurality of heat sinks 120 are disposed on at least one side of the circuit board 110. For example, the heat sinks 120 may be disposed on both sides of the circuit board 110. The surface of the circuit board 110 is parallel to a first direction, which extends from the air inlet to the air outlet. The fan assembly 220 is disposed on a side of the housing 210 close to the air inlet.

Illustratively, three working assemblies 100 are shown in FIG. 9A, and the three working assemblies 100 are arranged at intervals along a direction perpendicular to the surface of the circuit board 110. The heat sinks 120 may each include a heat sink body 121 and a plurality of heat sink fins 122. The plurality of heat sink fins 122 are disposed on a side surface of the heat sink body 121 at intervals along a second direction (for example, the up-down direction in FIG. 9A), wherein the second direction is perpendicular to the first direction and parallel to the surface of the circuit board 110.

The heat sink body 121 of the first heat sink 123 may contact the heat-generating components 111 on the first surface, and the heat sink body 121 of the second heat sink 124 may contact the second surface of the circuit board 110. The heat generated during the operation of the heat-generating components 111 may be conducted to the first heat sink 123 and the second heat sink 124. A heat dissipation channel extending along the first direction may be defined between two adjacent heat sink fins 122 and the heat sink body 121. When the fan assembly 220 is working, cold air enters from the air inlet, flows along the heat dissipation channels of the first heat sink 123 and the second heat sink 124, and exchanges heat with the first heat sink 123 and the second heat sink 124. The hot air, after heat exchange, flows out from the air outlet, thereby achieving heat dissipation of the working assembly 100.

By disposing the fan assembly 220 on the side of the housing 210 close to the air inlet so that the fan assembly 220 and the air outlet are located on both sides of the housing 210, when part of the working assembly 100 is damaged, it is only necessary to remove the damaged working assembly 100 and take it out from the air outlet, and then put the working assembly 100 with intact function into the housing 210 through the air outlet and install it, without removing the fan assembly 220. This facilitates the installation and disassembly of the working assembly 100, and can effectively improve the inspection and replacement efficiency of the working assembly 100.

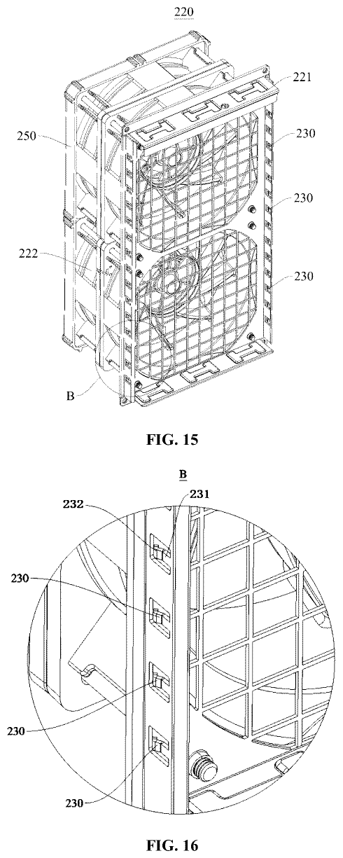

In one implementation, with reference to FIGS. 9A-15, the fan assembly 220 includes a mounting member 221 and a plurality of fan modules 222. The mounting member 221 is connected to the housing 210, and the plurality of fan modules 222 are connected to a side of the mounting member 221 facing away from the housing 210. For example, in the examples of FIGS. 15, 17 and 18, the mounting member 221 is greater than the fan module 222 in outline dimension. The portion of the mounting member 221 opposite to the fan module 222 is formed with a plurality of air inlet holes. When the fan module 222 is working, external air enters the heat-dissipating air duct through the plurality of air inlet holes under the action of the fan module 222, exchanges heat with the first heat sink 123 and the second heat sink 124, and then flows out from the air outlet.

Therefore, by disposing the mounting member 221 and the plurality of fan modules 222 described above, the mounting member 221 can firmly fix the fan module 222 on the housing 210, thereby improving the structural stability and reliability of the entire electronic device 200. The plurality of fan modules 222 can increase the ventilation volume of the heat-dissipating air duct, reduce air resistance, and inhibit the deposition of dust on the heat sink 120, thereby effectively improving the heat dissipation effect of the working assembly 100.

In one implementation, as shown in FIGS. 11 and 14-16, at least one first elastic component is provided on the mounting member 221, and the first elastic component is compressed between the mounting member 221 and the corresponding side wall of the housing 210 to achieve a secure installation between the mounting member 221 and the housing 210, and prevent the mounting member 221 from falling off the housing 210.

In one implementation, as shown in FIGS. 11 and 14-16, the mounting member 221 includes a mounting body, a mounting top plate and a mounting bottom plate that are oppositely disposed, two mounting side plates, and a first bent portion. The fan module 222 is connected to the installation body. A plurality of air inlet holes are formed on the installation body. The mounting top plate and the mounting bottom plate are disposed on a side of the mounting body facing away from the fan module. The mounting top plate is connected to the upper part of the mounting body, and the mounting bottom plate is connected to the lower part of the mounting body. The two mounting side plates are disposed on a side of the mounting body facing away from the fan module 222. Furthermore, the two mounting side plates are respectively connected to two sides of the mounting body. The first elastic component is disposed on at least one of the two mounting side plates. The first bent portion is connected to an end of the mounting top plate facing away from the mounting body.

Illustratively, in combination with FIGS. 11 and 13-16, the mounting top plate, the mounting bottom plate and the mounting side plates may all be perpendicular to the mounting body. The mounting top plate is connected between the mounting body and the first bent portion, and the first bent portion is parallel to the mounting body. After installation, the working assembly 100 may abut against the first bent portion, so that, on the one hand, there is a certain gap between the mounting member 221 and the working assembly 100 in the first direction. When the external air enters the heat-dissipating air duct from the fan module 222, it can flow evenly in the gap between the mounting member 221 and the working assembly 100, and then flow through the first heat sink 123 and the second heat sink 124 to improve the heat dissipation effect. On the other hand, the first bent portion may play an effective role in blocking the air, so that the air entering from the air inlet may flow into the working assembly 100 as much as possible, thereby avoiding the waste of air volume.

A plurality of I-shaped reinforcing ribs may be provided on the mounting top plate and the mounting bottom plate to prevent the mounting top plate and the mounting bottom plate from bending and warping, thereby improving the structural strength of the entire mounting component 221 and ensuring the structural stability of the electronic device 200.

In one implementation, the at least one first elastic component includes a plurality of first elastic clips 230 spaced apart from each other up and down, and free ends of the first clastic clips are compressed between the mounting side plate and the corresponding side wall of the housing.

Illustratively, a plurality of mounting holes spaced apart from each other in the up-down direction may be formed on the mounting side plate, and a plurality of first elastic clips 230 are disposed in the plurality of mounting holes in a one-to-one correspondence. One end of each first elastic clip 230 is connected to the edge of the corresponding mounting hole, and the other end (i.e., the above-mentioned free end) of each first elastic clip 230 extends in a direction opposite to the first direction. When the mounting member 221 is mounted on the housing 210, the side wall of the housing 210 presses the other end of each first elastic clip 230, so that each first elastic clip 230 generates elastic deformation. When the mounting member 221 is removed from the housing 210, the first elastic clip 230 returns to its original state. Each first elastic clip 230 is made of metal.

In one example, as shown in FIG. 16, each first clastic clip 230 may include a connection portion 231 and an abutment portion 232. One end of the connection portion 231 is connected to the first edge of the corresponding mounting hole. One end of the abutment portion 232 is connected to the other end of the connection portion 231, and the other end of the abutment portion 232 is spaced apart from the opposite-side edge of the first edge. The abutment portion 232 abuts against the corresponding side wall of the housing 210.

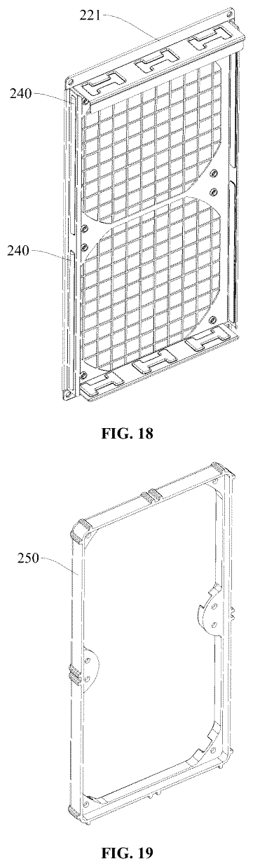

Therefore, the mounting member 221 and the housing 210 may be electrically connected via the plurality of first elastic clips 230, thereby playing an effective shielding and grounding role and improving the safety of the electronic device 200. In another implementation, with reference to FIG. 18 in combination with FIG. 11, the at least one first elastic component described above includes a first conductive foam 240 extending in the up-down direction, and the mounting member 221 is in elastic contact with the corresponding side wall of the housing 210 through the first conductive foam 240. For example, the first conductive foam 240 may be adhered to the two mounting side plates by an adhesive. Optionally, the first conductive foam 240 may be a conductive foam, but is not limited thereto. As such, the mounting member 221 and the housing 210 may be electrically connected via the first conductive foam 240, thereby also playing an effective shielding and grounding role and improving the safety of the electronic device 200.

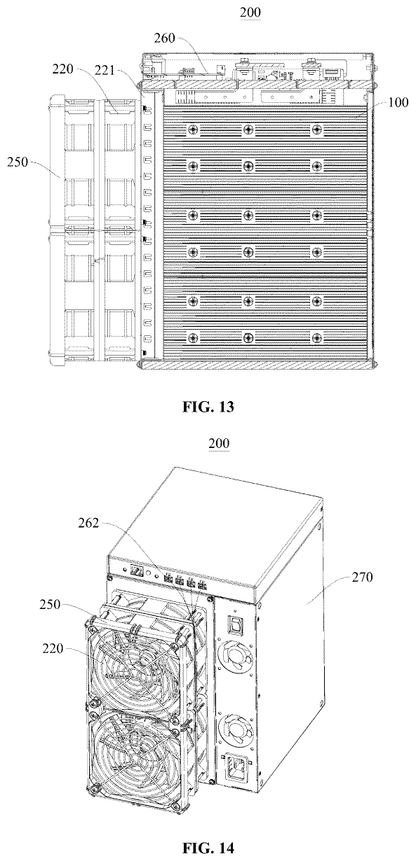

In one implementation, as shown in FIG. 13, the fan module 222 and the working assembly 100 are spaced apart in the first direction. For example, in the example of FIG. 13, there is a certain gap between the mounting member 221 and the working assembly 100 in the first direction. When the external air enters the heat-dissipating air duct from the fan module 222, it can flow evenly in the gap between the mounting member 221 and the working assembly 100, and then flow through the first heat sink 123 and the second heat sink 124. Thus, the gap between the fan module 222 and the working assembly 100 may allow air to flow into the heat sink 120 more evenly, thereby improving the heat dissipation effect.

In one implementation, with reference to FIGS. 14-19, a flexible protective cover 250 is disposed on a side of the fan module 222 that is away from the mounting plate, and the flexible protective cover 250 is sleeved on an outer periphery of the fan module 222. Therefore, the flexible protective cover 250 configured in this way can effectively protecting the edges and corners of the fan module 222, thus preventing the fan module 222 from being worn, and it may prevent the edges and corners of the fan module 222 from scratching workers, thereby improving safety. Optionally, the material of the flexible protective cover 250 may be soft rubber material, but is not limited thereto.

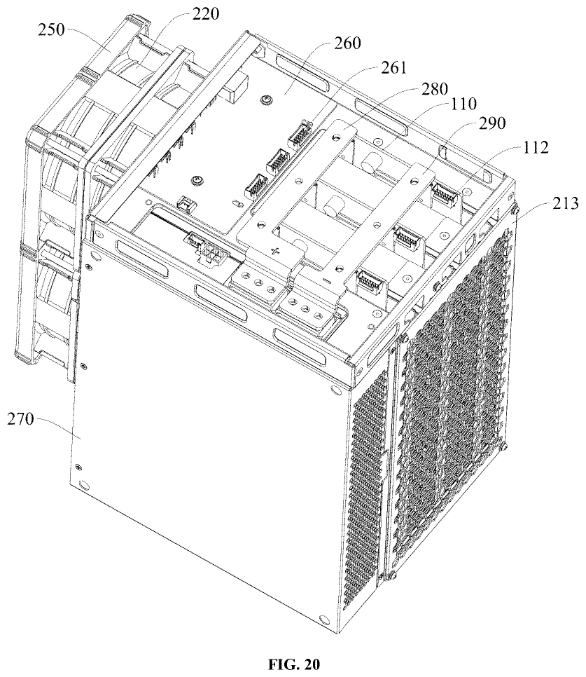

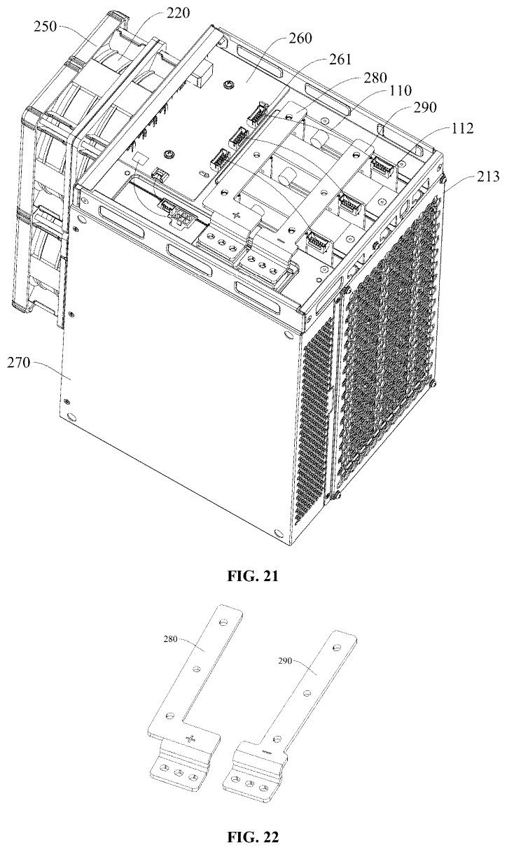

In one implementation, as shown in FIGS. 20 and 21, a control board 260 is provided on the top of the housing 210, and a plurality of fan interfaces 262 are provided on the control board 260. The plurality of fan interfaces 262 are connected to the plurality of fan modules 222 in a one-to-one correspondence, wherein the plurality of fan interfaces 262 are all disposed close to the air inlet. As such, the plurality of fan interfaces 262 are disposed close to the plurality of fan modules 222, which facilitates the wiring between the plurality of fan interfaces 262 and the plurality of fan modules 222.

Illustratively, a first signal socket 112 is disposed on the circuit board 110, and a second signal socket 261 is disposed on the control board 260, and the second signal socket 261 is connected to the first signal socket 112. For example, in the examples of FIGS. 20 and 21, there are three second signal sockets 261, and the three second signal sockets 261 may be connected one-to-one with the circuit boards 110 of the three working assemblies 100 through three first cables, so that the control board 260 can control the operation of the circuit board 110.

Illustratively, the second signal sockets 261 are close to the first signal sockets 112. Illustratively, when there are three second signal sockets 261, there are three first signal sockets 112, wherein the three second signal sockets 261 are disposed on a side of the control board 260 close to the first signal sockets 112. Such a configuration may facilitate the connection between the second signal sockets 261 and the first signal sockets 112 using the shortest connection line.

Illustratively, there are four fan interfaces 262 and four fan modules 222, and the four fan interfaces 262 may be connected to the four fan modules 222 in a one-to-one correspondence through four second cables, so that the control board 260 can control the operation of the working modules.

Illustratively, the four fan modules 222 are divided into two groups, and two fan modules 222 in each group are connected together by screws and fixed to the mounting member 221 by screws. Each fan module 222 is provided with through holes at four corners for screws to pass through, and correspondingly, the mounting member 221 is provided with threaded holes 2211 for screws to pass through to achieve assembly between the fan module 222 and the mounting member. Illustratively, the mounting member 221 is further provided with a plurality of fixing holes 2212 for fixing the mounting member 221 to the housing 210. For example, four fixing holes 2212 are provided at the four corners of the mounting member 221, and correspondingly, fixing holes are provided on the housing 210.

Therefore, with the above configuration, on the one hand, signal connection between the control board 260 and the fan module 222 and between the control board 260 and the circuit board 110 can be achieved; on the other hand, by disposing all of the plurality of fan interfaces 262 close to the air inlet, the plurality of fan interfaces 262 can be centrally disposed on the control board 260, and the structure is more compact, occupying less space, and facilitating the spatial layout of other modules on the control board 260.

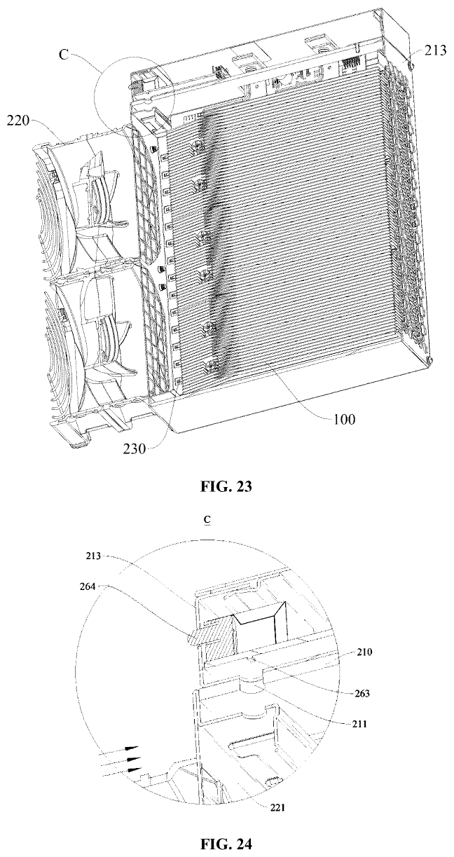

In one implementation, with reference to FIGS. 23-25B, a top housing 212 is disposed on the top of the housing 210, and a control board 260 is disposed in the top housing 212. The control board 260 is provided with a temperature sensor 263 for sensing the temperature at the air inlet. In this way, a user may know the temperature at the air inlet in real time, avoid the temperature of the air entering from the air inlet being too high, and endow the working assembly 100 with a better heat dissipation effect, thereby ensuring the normal operation of the working assembly 100 and effectively extending the service life of the entire electronic device 200.

In one implementation, as shown in FIGS. 23 and 24, the temperature sensor 263 is disposed at the bottom of the control board 260, and the temperature sensor 263 is located within the top housing 212. The top surface of the housing 210 is formed with a vent 211 connected to the heat-dissipating air duct, and the ventilation hole 211 corresponds to the temperature sensor 263 in position. For example, in the examples of FIGS. 23 and 24, a first vent penetrating in the thickness direction is formed on the top of the mounting member 221, and the first vent, the vent 211 and the temperature sensor 263 correspond to each other in the up-down direction.

Therefore, the temperature sensor 263 in the above implementations can sense the temperature at the air inlet through the vent 211, thereby ensuring that the air input from the air inlet is cold air. Moreover, the temperature sensor 263 may be hidden in the top housing 212 to prevent the temperature sensor 263 from direct contact with the external environment, so that the top housing 212 may effectively protect the temperature sensor 263 and prevent the temperature sensor 263 from being damaged, and may make the appearance of the electronic device 200 more neat and beautiful.

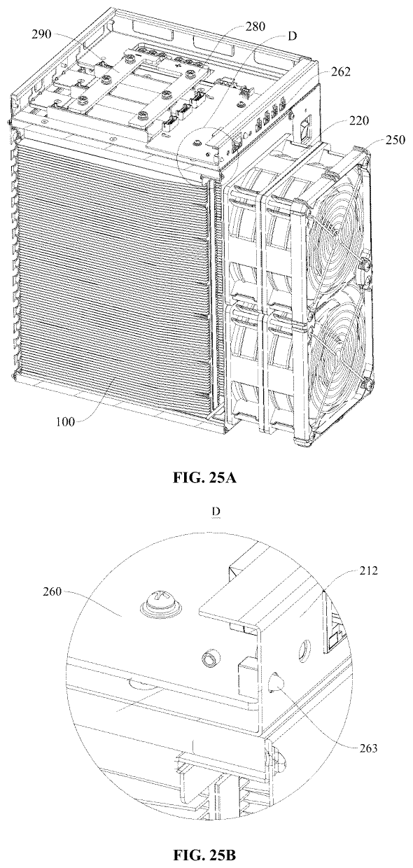

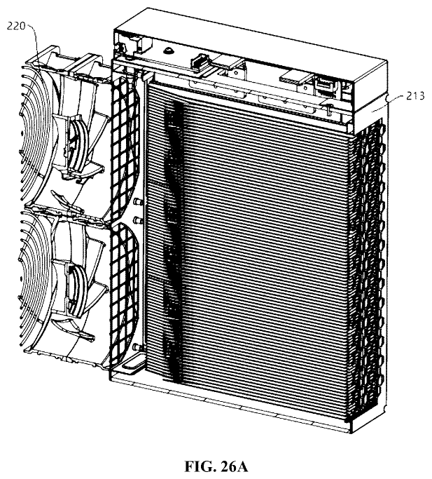

In another implementation, with reference to FIGS. 25A and 25B, the temperature sensor 263 is disposed on the top of the control board 260, and the temperature sensor 263 protrudes from a side surface of the top housing 212 close to the fan assembly 220. For example, in the examples of FIGS. 25A and 25B, a passage hole may be formed on the side of the top housing 212 close to the air inlet, the temperature sensor 263 may be set on the side of the control board 260 close to the air inlet, and the temperature sensor 263 protrudes out of the top housing 212 from the passage hole. With such configuration, the temperature sensor 263 can directly protrude out of the top housing 212 to sense the temperature at the air inlet, and no holes need to be opened on the housing 210 and the mounting member 221, thereby making the structure of the housing 210 simpler and easier to process.

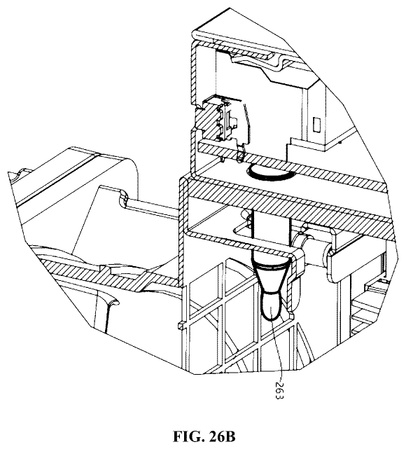

Of course, the present application is not limited thereto. In another implementation, as shown in FIGS. 26A and 26B, the free end of the temperature sensor 263 may pass through the top of the housing 210 and protrude into the housing 210 and be opposite to the fan assembly 220. As such, the free end of the temperature sensor 263 can protrude into an air inlet cavity of the housing 210 to detect the temperature of the air input by the fan assembly 220, and can sense the temperature of the air inlet more accurately.

In the process of implementing the present invention, the inventors found that the indicator light of the electronic device 200 is usually disposed in the middle of the control board of the electronic device 200. When a plurality of fans are connected in series (for example, 4 fans) and installed on a front face of the electronic device 200, due to the viewing angle, the fan will block the indicator light, affecting the observation of the operation and maintenance personnel, especially when the electronic device 200 needs to be placed on a rack, sometimes at a higher position, in which case the fan will more easily block the indicator light.

Based on this observation, in one implementation, as shown in FIGS. 23 and 24, the electronic device 200 may further include an indicator light 264 to indicate the working status of the electronic device 200. The indicator light 264 is disposed on a side of the control board close to the air inlet, and is located at an end of the control board near the side of the air inlet.

Since the indicator light 264 is disposed at the end of the side of the control board, the indicator light may be observed from one side of the mining machine, thus avoiding the situation where the fan blocks the indicator light.

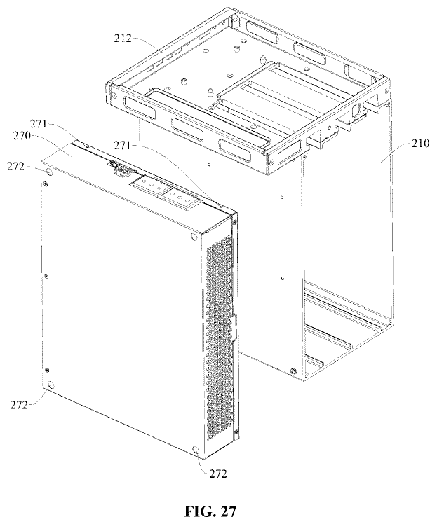

In one implementation, as shown in FIGS. 27-29B, the electronic device 200 further includes: a power module 270 disposed on one side of the housing 210 in a third direction and configured to supply power to the circuit board 110 and the fan assembly 220, wherein the third direction is perpendicular to the surface of the circuit board 110.

Illustratively, the housing 210 is generally a rectangular parallelepiped structure, and the housing 210 may include a top surface, a bottom surface, and four side surfaces, and the four side surfaces are respectively connected between the top surface and the bottom surface. The top surface and the bottom surface are opposite to each other in the second direction. The top of the power module 270 is connected to the top housing 212, and the side surface of the power module 270 is connected to side surface of the housing 210.

Along the third direction, the top housing 212 includes two first side surfaces that are opposite to each other and two second side surfaces that are opposite to each other, wherein one of the two first side surfaces is flush with the corresponding fourth side surface of the housing 210, the other of the two first side surfaces is flush with the corresponding side surface of the power module 270, each second side surface is flush with the corresponding side surfaces of the housing 210 and the power module 270 at the same time, and the bottom surface of the power module 270 is flush with the bottom surface of the housing 210.

Specifically, for example, the two first side surfaces of the top housing 212 may be a front side surface and a rear side surface, respectively, and the two second side surfaces of the top housing 212 may be a left side surface and a right-side surface, respectively. The front side surface of the top housing 212 may be flush with the front side of the housing 210 and the front side of the power module 270, the rear side surface of the top housing 212 may be flush with the rear side surface of the housing 210 and the rear side surface of the power module 270, the left side surface of the top housing 212 may be flush with the left side surface of the housing 210, the right side surface of the top housing 212 may be flush with the right side surface of the power module 270, and the bottom surface of the power module 270 is flush with the bottom surface of the housing 210.

It should be noted that the above-mentioned “front” refers to the direction close to the air inlet of the heat-dissipating air duct, and the opposite direction is defined as “rear”, that is, the direction close to the air outlet of the heat-dissipating air duct. “Left” refers to the direction extending along the power module 270 toward the housing 210; and “right” refers to the direction extending along the housing 210 toward the power module 270. Correspondingly, the “front side surface” refers to the side surface close to the air inlet of the heat-dissipating air duct, and the “rear side surface” refers to the side surface close to the air outlet of the heat-dissipating air duct. The “left side surface” refers to the side surface in the direction from the power module 270 toward the housing 210, and the “right side” refers to the side surface in the direction from the housing 210 toward the power module 270.

Therefore, through the above-mentioned power module 270, while supplying power to the circuit board 110 and the fan assembly 220, the power module 270 may effectively utilize the space between the top housing 212 and the housing 210, thereby making the structure of the entire electronic device 200 more compact and the appearance neater and more beautiful.

In one implementation, as shown in FIGS. 27-30B, at least one positioning hole 271 is formed on one of the power module 270 and the top housing 212, and at least one positioning protrusion is provided on the other of the power module 270 and the top housing 212, and the positioning protrusion are fitted into the corresponding positioning hole 271. At least one through hole 272 is formed on one of the power module 270 and the housing 210, and at least one threaded hole corresponding to the through hole 272 is formed on the other of the power module 270 and the housing 210. The threaded fastener 273 is suitable for passing through the through hole 272 and being threadedly connected with the threaded hole.

For example, in the examples of FIGS. 27-30B, two positioning holes 271 are formed on the top of the power module 270, and the two positioning holes 271 are disposed at intervals along the first direction. Correspondingly, two positioning protrusions disposed at intervals in the first direction may be disposed on the bottom surface of the top housing 212, and the two positioning protrusions correspond one-to-one to the two positioning holes 271. Four through holes 272 are formed on a side surface of the power module 270, and the four through holes 272 are respectively located at the four corners of the power module 270. Four threaded holes corresponding to the four through holes 272 are formed on the second side surface of the housing 210. During installation, the two positioning protrusions may be respectively fitted into the corresponding positioning holes 271 to achieve positioning of the power module 270. Then, four threaded fasteners 273 are respectively passed through the corresponding through holes 272 and threadedly connected with the corresponding threaded holes to fix the power module 270.

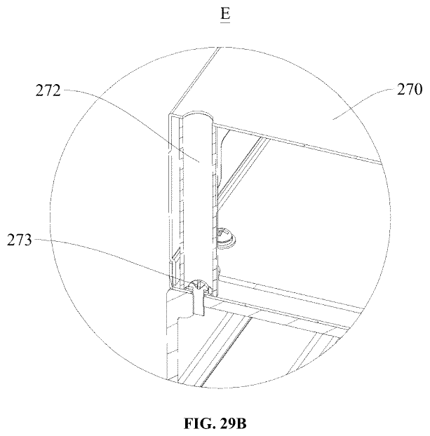

In one example, as shown in FIGS. 29A and 29B, all the threaded fastener 273 may be short screws. At this time, the threaded fasteners 273 may pass through one of the side walls of the power module 270 and be threadedly connected to the threaded hole on the housing 210. At this time, one of the side walls of the power module 270 is compressed between the head of the threaded fastener 273 and the housing 210.

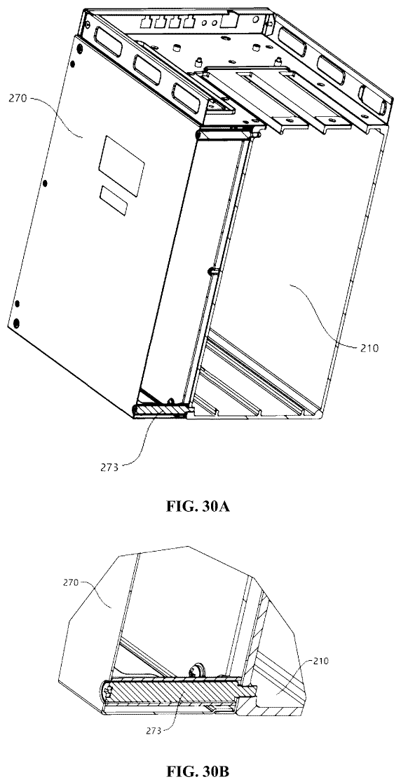

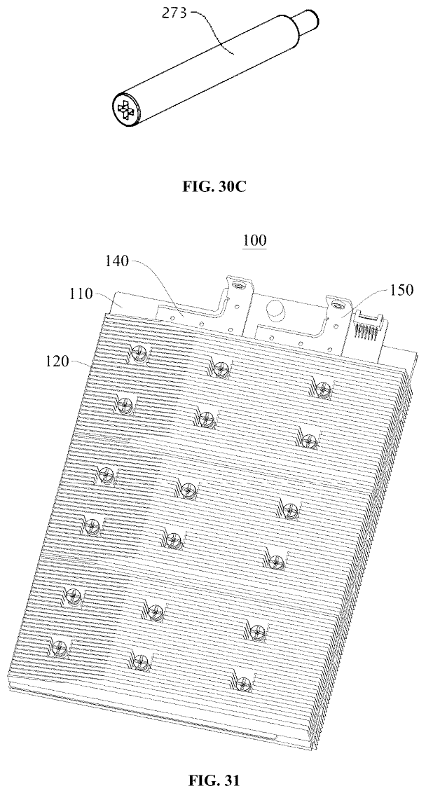

In another example, as shown in FIGS. 30A-30C, all the threaded fastener 273 may be long screws. At this time, the threaded fasteners 273 may pass through two side walls of the power module 270 and be threadedly connected to the threaded hole on the housing 210. At this time, the entire power module 270 is compressed between the head of the threaded fastener 273 and the housing 210. This fixing method has better visibility and facilitates the installation and removal of threaded fasteners 273 such as screws.

Of course, it is also possible to have some threaded fasteners 273 as short screws and others as long screws, which is not limited in the present application.

Therefore, the power module 270 may be positioned relative to the housing 210 in advance by cooperation of the positioning protrusion and the positioning hole 271, preventing the power module 270 from shifting during the process of being assembled with the housing 210, thereby improving installation efficiency. Moreover, the power module 270 and the housing 210 may be directly threadedly connected via the threaded fastener 273, eliminating the need for a bracket between the power module 270 and the housing 210 and making the structure simpler.

In one implementation, with reference to FIGS. 20-22, the electronic device 200 further includes a first conductive connector 280 and a second conductive connector 290. Specifically, a portion of the first conductive connector 280 is electrically connected to the power module 270, and another portion of the first conductive connector 280 is electrically connected to the first connection socket 140 of the working assembly 100. A portion of the second conductive connector 290 is electrically connected to the power module 270, and another portion of the first conductive connector 290 is electrically connected to the second connection socket 150 of the working assembly 100.

For example, in the examples of FIGS. 20-22, the bottom surface of the above-mentioned other part of the first conductive connector 280 may contact the top surface of the third connection segments of the three first connection bases 140, and the first fastener is suitable for passing through the first conductive connector 280 to connect with the third connection segment of the corresponding first connection base 140. The bottom surface of the above-mentioned other part of the second conductive connector 290 may contact the top surface of the second connection segments of the three second connection bases 150, and the second fastener is suitable for passing through the second conductive connector 290 to connect with the third connection segment of the corresponding second connection base 150. The above-mentioned other portion of the first conductive connector 280 may be parallel to the above-mentioned other portion of the second conductive connector 290, and both may extend along the third direction. The first conductive connector 280 may be a positive electrode conductive bar, and the second conductive connector 290 may be a negative electrode conductive bar.

Therefore, by disposing the first conductive connector 280 and the second conductive connector 290 described above, electrical connection between the power module 270 and the circuit board 110 may be achieved, so that current may be input from the power module 270 into the circuit board 110 to achieve power supply for the circuit board 110. Moreover, the first conductive connector 280 and the second conductive connector 290 have simple structures and are easy to arrange.

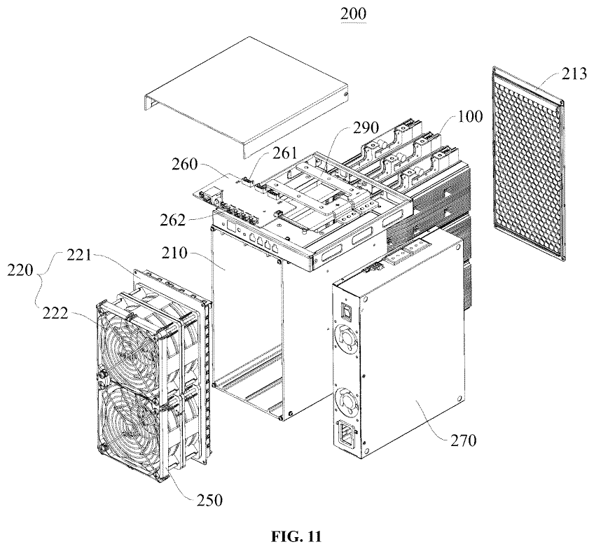

In one implementation, as shown in FIGS. 9A-10B, an air outlet panel 213 is provided at the air outlet of the housing 210, at least one second elastic component is provided at the edge of the air outlet panel 213, and the second elastic component is compressed between the air outlet panel 213 and the corresponding side wall of the housing 210. Therefore, by providing the above-mentioned second elastic component, the second elastic component may be squeezed into the housing 210, so that the connection between the air outlet panel 213 and the housing 210 is more stable, and the air outlet panel 213 is prevented from falling off from the housing 210.

In one implementation, the air outlet panel 213 includes an air outlet main body, an air outlet top plate and an air outlet bottom plate that are oppositely disposed, two air outlet side plates, and a second bent portion. A plurality of air outlet holes are formed on the air outlet main body. The air outlet top plate and the air outlet bottom plate are disposed on one side surface of the air outlet main body. The air outlet top plate is connected to the upper part of the air outlet main body, and the air outlet bottom plate is connected to the lower part of the air outlet main body. The two air outlet side plates are disposed on one side surface of the air outlet main body, and the two air outlet side plates are respectively connected to the two sides of the air outlet main body. The second elastic component is disposed on at least one of the two air outlet side plates. The second bent portion is connected to an end of the air outlet top plate facing away from the air outlet main body, and is located between the air outlet top plate and the air outlet bottom plate.

Illustratively, the air outlet bottom plate and each air outlet side plate may be perpendicular to the air outlet main body. The air outlet top plate is connected between the air outlet main body and the second bent portion. After installation, the working assembly 100 may abut against the second bent portion, so that the air flowing through the first heat sink 123 and the second heat sink 124 can better flow out through the air outlet, further improving the heat dissipation effect.

In one example, as shown in FIGS. 9A and 9B, the at least one second elastic component includes a plurality of second elastic clips 214 spaced apart along the second direction, and the second clastic clips 214 are compressed between the air outlet panel 213 and the corresponding side wall of the housing 210.

For example, a plurality of spaced slots spaced apart from each other in the up-down direction may be formed on the air outlet side plate, and a portion of the air outlet side plate located between two adjacent spaced slots is the second elastic clip 214. During installation, the two air outlet side panels are squeezed into the corresponding side walls of the housing 210. At this time, the plurality of second elastic clips 214 are elastically deformed. Then, the air outlet panel 213 is threadedly connected to the housing 210 via threaded fasteners. During disassembly, only the threaded fasteners need to be removed, and then the air outlet panel 213 is pulled out. At this time, the plurality of second elastic clips 214 return to their original state.

In another example, the above-mentioned at least one second elastic component includes a second conductive foam 215 extending along the second direction. With such a configuration, it is possible that while achieving a firm connection between the air outlet panel 213 and the housing 210, it also allows that the air outlet panel 213 and the housing 210 may be electrically connected via the second conductive foam 215, thereby providing effective shielding and grounding, further improving the safety of the electronic device 200.

In one implementation, at least one baffle is disposed on the top of the housing 210, and the baffle corresponds to the heat sink 120 in position. As such, the air blown out by the fan module 222 may be evenly blown to a plurality of heat sinks 120, preventing a portion of the air from blowing into the top housing 212 located on the top of the housing 210, thereby increasing the ventilation volume in the heat-dissipating air duct, avoiding dust accumulation on the heat sink 120, and further improving the heat dissipation effect.

In the description of the present specification, It can be appreciated that orientations or positional relationships indicated by terms such as “central”, “longitudinal”, “lateral”, “length”, “width”, “thickness”, “up”, “down”, “front”, “back”, “left”, “right”, “vertical”, “horizontal”, “top”, “bottom”, “inside”, “outside”, “clockwise”, “counterclockwise”, “axial”, “radial”, “circumferential” and the like are orientations or positional relationships based on the drawings, which are only for the convenience of describing the present application and simplifying the description, and do not indicate or imply that the referred device or element must have a specific orientation, be constructed and operated in a specific orientation, and therefore should not be understood as a limitation on the present application.

In addition, terms such as “first” and “second” are used for descriptive purposes only and cannot be understood as indicating or implying relative importance or implicitly indicating the quantity of the indicated technical features. Therefore, a feature defined as “first” or “second” may explicitly or implicitly include one or more of the features. In the description of the present application, “a/the plurality of” means two or more than two, unless otherwise clearly and specifically defined.

In the present application, unless otherwise clearly specified and limited, terms such as “mount”, “link”, “connect”, “fix”, etc. and variants thereof should be understood in a broad sense. For example, it may be a fixed connection, or may be a detachable connection, or formed into one piece. It may be a mechanical connection, an electrical connection, or a communication connection. It may be a direct connection or an indirect connection through an intermediate medium. It may be an internal communication between two elements or an interaction relationship between two elements. For those of ordinary skill in the art, the specific meanings of the above terms in the present application may be understood according to specific circumstances.

In the present application, unless otherwise clearly specified and limited, a first feature being “on” or “under” a second feature may include the first and second features being in direct contact, or may include the first and second features not being in direct contact but being in contact through another feature between them. Moreover, a first feature being “over”, “above”, or “onto” a second feature includes the first feature being directly above or obliquely above the second feature, or simply means that the first feature is at a higher horizontal stage than the second feature. A first feature being “under”, “below”, or “beneath” a second feature includes the first feature being directly below or diagonally below the second feature, or simply means that the first feature is at a lower horizontal stage than the second feature.

The above disclosure provides many different embodiments or examples for implementing different structures of the present application. In order to simplify the disclosure of the present application, components and arrangements of specific examples are described above. Of course, they are merely examples and are not intended to limit the present application. In addition, the present application may repeat reference numerals and/or reference letters in different examples. Such repetition is for the purpose of simplicity and clarity, which is not aimed to indicate relationships between various embodiments and/or arrangements discussed.

The above are only detailed description of the present application, the protection scope of the present application is not limited thereto. Any technician familiar with the technical field may easily conceive of various changes or substitutions within the technical scope disclosed in the present application, which should all be encompassed in the protection scope of the present application. Therefore, the protection scope of the present application should be based on the protection scope of the claims.

What is claimed is:

1. A conductive assembly for an electronic device, the electronic device comprises a working assembly, a power module and a heat-dissipating air duct, the heat-dissipating air duct extends along a first direction and is located between an air inlet and an air outlet, the working assembly is disposed in the heat-dissipating air duct; the conductive assembly comprises:
a first conductive connector configured to electrically connect a positive electrode terminal of the working assembly with a positive electrode terminal of the power module; and
a second conductive connector configured to electrically connect the positive electrode terminal of the working assembly with the positive electrode terminal of the power module.

2. The conductive assembly for the electronic device as claimed in claim 1, wherein the positive electrode terminal and a negative electrode terminal of the working assembly face a second direction, the positive electrode terminal and a negative electrode terminal of the power module face the second direction, and the second direction is perpendicular with the first direction; and
the conductive assembly is located on the same side of the working assembly and the power module in the second direction.

3. The conductive assembly for the electronic device as claimed in claim 1, wherein each of the first conductive connector and the second conductive connector is a conductive bar, the working assembly and the power module are adjacently arranged in a third direction, a first working assembly connecting segment of the first conductive connector extends along the third direction, a second working assembly connecting segment of the second conductive connector extends along the third direction, and the third direction is perpendicular with a second direction.

4. The conductive assembly for the electronic device as claimed in claim 1, wherein the first conductive connector and the second conductive connector are arranged side by side and spaced apart in the first direction.

5. The conductive assembly for the electronic device as claimed in claim 1, wherein the working assembly comprises a plurality of circuit boards arranged at intervals in a third direction, the first conductive connector is configured to electrically connect a positive electrode terminal of each circuit board with the positive electrode terminal of the power module, and the second conductive connector is configured to electrically connect a negative electrode terminal of each circuit board with a negative electrode terminal of the power module.

6. The conductive assembly for the electronic device as claimed in claim 3, wherein planes on which the first working assembly connecting segment and a first power supply connecting segment of the first conductive connector are respectively located are not flush;
and/or planes on which the second working assembly connecting segment and a second power supply connecting segment of the second conductive connector are respectively located are not flush.

7. The conductive assembly for the electronic device as claimed in claim 6, wherein the third direction is a horizontal direction;
a top surface of the working assembly in the third direction is higher than a top surface of the power module in the third direction, and the plane on which the first working assembly connecting segment is located is higher than the plane on which the first power connecting segment is located;
and/or the top surface of the working assembly in the third direction is higher than the top surface of the power module in the third direction, and the plane on which the second working assembly connecting segment is located is higher than the plane on which the second power connecting segment is located.

8. The conductive assembly for the electronic device as claimed in claim 6, wherein the first conductive connector further comprises a first transition connecting segment connected between the first working assembly connecting segment and the first power connecting segment;
and/or the second conductive connector further comprises a second transition connecting segment connected between the second working assembly connecting segment and the second power supply connecting segment.

9. The conductive assembly for the electronic device as claimed in claim 6, wherein a dimension of the first working assembly connecting segment in the third direction is larger than a dimension of the first power supply connecting segment in the third direction;
and/or a dimension of the second working assembly connecting segment in the third direction is greater than a dimension of the second power supply connecting segment in the third direction.

10. The conductive assembly for the electronic device as claimed in claim 6, wherein the first working assembly connecting segment is provided with at least one first working assembly connection hole, and the first working assembly connection hole is configured for a fastener to pass through so as to fixedly connect the first working assembly connecting segment with the positive electrode connecting terminal of the working assembly;
and/or the first power connecting segment is provided with at least one first power connection hole, and the first power connection hole is configured for a fastener to pass through so as to fixedly connect the first power connecting segment with the positive electrode terminal of the power module.

11. The conductive assembly for the electronic device as claimed in claim 10, wherein the first working assembly connecting segment is provided with at least one first working assembly connection hole, and the first working assembly connection hole is configured for a fastener to pass through so as to fixedly connect the first working assembly connecting segment with the positive electrode connecting terminal of the working assembly; wherein there are three first working assembly connection holes.

12. The conductive assembly for the electronic device as claimed in claim 6, wherein the second working assembly connecting segment is provided with at least one second working assembly connection hole, and the second working assembly connection hole is configured for a fastener to pass through so as to fixedly connect the second working assembly connecting segment with a negative electrode connecting terminal of the working assembly;
and/or the second power connecting segment is provided with at least one second power connection hole, and the second power connection hole is configured for a fastener to pass through so as to fixedly connect the second power connecting segment with the negative electrode terminal of the power module.

13. The conductive assembly for the electronic device as claimed in claim 12, wherein the second working assembly connecting segment is provided with at least one second working assembly connection hole, and the second working assembly connection hole is configured for a fastener to pass through so as to fixedly connect the second working assembly connecting segment with the negative electrode connecting terminal of the working assembly; wherein there are three second working assembly connection holes.

14. The conductive assembly for the electronic device as claimed in claim 1, wherein the first conductive connector is made of a material comprising copper or aluminum; and/or the second conductive connector is made of a material comprising copper or aluminum.

15. The conductive assembly for the electronic device as claimed in claim 1, wherein a maximum width of the first conductive connector is greater than a maximum width of the second conductive connector.

16. The conductive assembly for the electronic device as claimed in claim 15, wherein the ratio of the maximum width of the first conductive connector and the maximum width of the second conductive connector is in the range of 6/5 to 8/5.

17. The conductive assembly for the electronic device as claimed in claim 1, wherein a projection shape of a first working assembly connecting segment of the first conductive connector on a horizontal plane is L-shaped.

18. The conductive assembly for the electronic device as claimed in claim 1, wherein the first conductive connector and the second conductive connector have the same dimension in a third direction.

19. The conductive assembly for the electronic device as claimed in claim 1, wherein a projection area of the first conductive connector on a horizontal plane is larger than a projection area of the second conductive connector on a horizontal plane.

20. An electronic device, comprising:
a power module;
a working assembly comprising at least one circuit board; and
the conductive assembly as claimed in claim 1, configured to electrically connect the working assembly of the electronic device with the power module of the electronic device.
